(19) United States
(12) Patent Application Publication
(10) Pub. No.: US 2025/0081459 A1
(43) Pub. Date: Mar. 6, 2025

(54) THREE-DIMENSIONAL SEMICONDUCTOR MEMORY DEVICE AND ELECTRONIC SYSTEM INCLUDING THE SAME

(71) Applicant: SAMSUNG ELECTRONICS CO., LTD., SUWON-SI (KR)

(72) Inventors: SUSEONG NOH, Suwon-si (KR); KWANG-SOO KIM, Suwon-si (KR); ILHO MYEONG, Suwon-si (KR)

(21) Appl. No.: 18/601,009

(22) Filed: Mar. 11, 2024

(30) Foreign Application Priority Data
Sep. 5, 2023 (KR) 10-2023-0117922

(51) Int. Cl. H10B 43/27; H01L 21/28; H01L 23/528; H01L 25/065; H01L 29/51; H10B 43/10; H10B 43/35; H10B 43/40; H10B 80/00

(52) U.S. Cl. CPC H10B 43/27; H01L 23/5283; H01L 25/0652; H10B 43/10; H10B 43/35; H10B 43/40; H10B 80/00; H10D 64/033; H10D 64/689; H01L 2225/06506

(57) ABSTRACT

A three-dimensional semiconductor memory device may include a stack including gate electrodes and insulating layers, which are alternatingly stacked on a substrate, vertical channel structures penetrating the stack, and data storage patterns between the stack and the vertical channel structures. The data storage patterns may be spaced apart from each other in a direction perpendicular to a top surface of the substrate, and each of the data storage patterns may include a ferroelectric pattern, an anti-ferroelectric pattern, and a first insulating pattern.

### CROSS-REFERENCE TO RELATED APPLICATIONS

This U.S. non-provisional patent application claims priority under 35 U.S.C. § 119 to Korean Patent Application No. 10-2023-0117922, filed on Sep. 5, 2023, in the Korean Intellectual Property Office, the entire contents of which are hereby incorporated by reference.

### BACKGROUND OF THE INVENTION

The present disclosure relates to a three-dimensional semiconductor memory device, and in particular, a nonvolatile three-dimensional semiconductor memory device including a vertical channel structure, a method of fabricating the same, and an electronic system including the same.

A semiconductor device capable of storing a large amount of data can be utilized as a data storage of an electronic system. Higher integration of semiconductor devices is used to satisfy consumer demands for large data storing capacity, superior performance, and inexpensive prices. In the case of two-dimensional or planar semiconductor devices, because the integration is mainly determined by the area occupied by a unit memory cell, integration is greatly influenced by the level of fine pattern forming technology. However, the extremely expensive process equipment needed to increase pattern fineness sets a practical limitation on increasing integration for two-dimensional or planar semiconductor devices. Thus, three-dimensional semiconductor memory devices including three-dimensionally arranged memory cells have recently been proposed.

### SUMMARY

An embodiment of the inventive concept provides a three-dimensional semiconductor memory device with improved electrical and reliability characteristics.

An embodiment of the inventive concept provides an electronic system including a three-dimensional semiconductor memory device with improved electrical and reliability characteristics.

According to an embodiment of the inventive concept, a three-dimensional semiconductor memory device may include a stack including alternatingly stacked gate electrodes and insulating layers on a substrate, vertical channel structures penetrating the stack, and data storage patterns between the stack and the vertical channel structures. The data storage patterns may be spaced apart from each other in a direction perpendicular to a top surface of the substrate, and each of the data storage patterns may include a ferroelectric pattern, an anti-ferroelectric pattern, and a first insulating pattern.

According to an embodiment of the inventive concept, a three-dimensional semiconductor memory device may include a substrate including a cell array region and a connection region; a stack including alternatingly stacked gate electrodes and insulating layers on the substrate; vertical channel structures on the cell array region that penetrate the stack and electrically connect to the substrate; a planarization insulating layer on the connection region that cover the stack; cell contact plugs on the connection region and penetrate the planarization insulating layer, and are electrically connected to the gate electrodes, respectively; bit lines on the stack and electrically connected to the vertical channel structures; and data storage patterns between the vertical channel structures and the gate electrodes, wherein each of the data storage patterns comprises a ferroelectric pattern including a ferroelectric material; an anti-ferroelectric pattern including an anti-ferroelectric material; and a first insulating pattern including a material different from the anti-ferroelectric pattern.

According to an embodiment of the inventive concept, an electronic system may include a three-dimensional semiconductor memory device including an input/output pad; and a controller electrically connected to the three-dimensional semiconductor memory device through the input/output pad that is configured to control the three-dimensional semiconductor memory device, wherein the three-dimensional semiconductor memory device further comprises a substrate including a cell array region and a connection region; a peripheral circuit structure provided on the substrate, the peripheral circuit structure comprising peripheral circuits electrically connected to the input/output pad; and a cell array structure comprising a stack, wherein the stack includes gate electrodes and insulating layers alternatingly stacked on the peripheral circuit structure, vertical channel structures, that penetrate the stack, and data storage patterns between the gate electrodes and the vertical channel structures, wherein each of the data storage patterns comprises a ferroelectric pattern, an anti-ferroelectric pattern, and an insulating pattern, and the ferroelectric pattern and the anti-ferroelectric pattern are between the insulating pattern and the vertical channel structures.

### BRIEF DESCRIPTION OF THE DRAWINGS

FIG. 1 is a diagram schematically illustrating an electronic system including a three-dimensional semiconductor memory device, according to an embodiment of the inventive concept.

FIG. 2 is a perspective view schematically illustrating an electronic system including a three-dimensional semiconductor memory device, according to an embodiment of the inventive concept.

FIGS. 3 and 4 are sectional views, which are taken along a line I-I′ of FIG. 2 to illustrate a semiconductor package including a three-dimensional semiconductor memory device, according to an embodiment of the inventive concept.

FIG. 5 is a plan view illustrating a three-dimensional semiconductor memory device, according to an embodiment of the inventive concept.

FIGS. 6A and 6B are sectional views, which are respectively taken along lines A-A′ and B-B′ of FIG. 5 to illustrate a three-dimensional semiconductor memory device, according to an embodiment of the inventive concept.

FIG. 7 is an enlarged perspective view illustrating a portion (e.g., P1 of FIG. 6A) of a three-dimensional semiconductor memory device, according to an embodiment of the inventive concept.

FIGS. 8A to 8D are enlarged sectional views illustrating a portion P2 of FIG. 7.

FIG. 9 is an enlarged sectional view illustrating a portion (e.g., P3 of FIG. 6A) of a three-dimensional semiconductor memory device, according to an embodiment of the inventive concept.

FIG. 10 is a sectional view illustrating a three-dimensional semiconductor memory device, according to an embodiment of the inventive concept.

FIGS. 11A to 17B are diagrams illustrating a method of fabricating a three-dimensional semiconductor memory device, according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their description may be omitted.

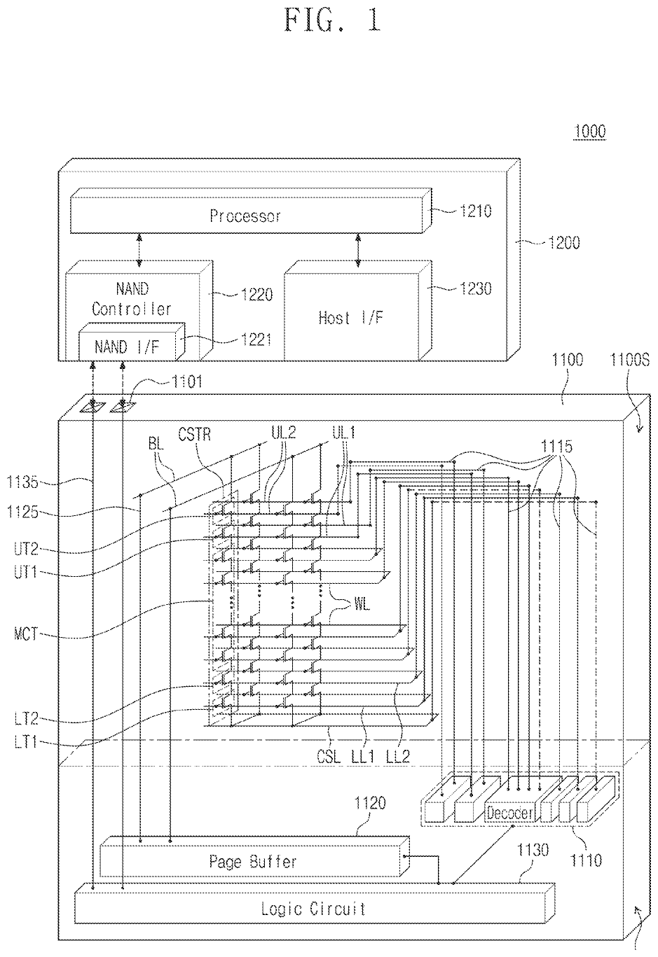

FIG. 1 is a diagram schematically illustrating an electronic system including a three-dimensional semiconductor memory device, according to an embodiment of the inventive concept.

Referring to FIG. 1, an electronic system 1000, according to an embodiment, may include a three-dimensional semiconductor memory device 1100 and a controller 1200, which is electrically connected to the three-dimensional semiconductor memory device 1100. The electronic system 1000 may be a storage device including the three-dimensional semiconductor memory device 1100 or an electronic device including a storage device. For example, the electronic system 1000 may be a solid state drive (SSD) device, a universal serial bus (USB), a computing system, a medical system, or a communication system, in which the three-dimensional semiconductor memory device 1100 is provided. In an embodiment, a plurality of three-dimensional semiconductor memory devices 1100 may be provided.

The three-dimensional semiconductor memory device 1100 may be a nonvolatile memory device (e.g., a NAND FLASH memory device). The three-dimensional semiconductor memory device 1100 may include a first structure 1100F and a second structure 1100S on the first structure 1100F, where the first structure 1100F may be adjoining the second structure 1100S. Alternatively, the first structure 1100F may be disposed beside the second structure 1100S, where the first structure 1100F may be laterally adjacent to the second structure 1100S.

In various embodiments, the first structure 1100F may be a peripheral circuit structure, which includes a decoder circuit 1110, a page buffer 1120, and a logic circuit 1130. The second structure 1100S may be a memory cell structure including bit lines BL, a common source line CSL, word lines WL, first and second gate upper lines UL1 and UL2, first and second gate lower lines LL1 and LL2, and memory cell strings CSTR between the bit lines BL and the common source line CSL.

In the second structure 1100S, each of the memory cell strings CSTR may include lower transistors LT1 and LT2 adjacent to the common source line CSL, upper transistors UT1 and UT2 adjacent to the bit lines BL, and a plurality of memory cell transistors MCT disposed between the lower transistors LT1 and LT2 and the upper transistors UT1 and UT2.

In various embodiments, each of the memory cell transistors MCT may include a data storing element, where the data storing element may include a ferroelectric material. By using the data storing element with the ferroelectric material, it may be possible to realize a three-dimensional semiconductor memory device that can be operated with low power and with a fast operation speed. The word lines WL may serve as gate electrodes of the memory cell transistors MCT. A voltage difference between the word lines WL and channel regions of the memory cell transistors MCT may be adjusted to cause a change in polarization of a dipole of the ferroelectric material, and this may be used to perform a data writing or erasing operation on the memory cell transistors MCT.

In various embodiments, the upper transistors UT1 and UT2 may include a string selection transistor, and the lower transistors LT1 and LT2 may include a ground selection transistor. The gate lower lines LL1 and LL2 may be used as respective gate electrodes of the lower transistors LT1 and LT2. The gate upper lines UL1 and UL2 may be used as respective gate electrodes of the upper transistors UT1 and UT2. In an embodiment, the number of the lower transistors LT1 and LT2 and the number of the upper transistors UT1 and UT2 may be variously and independently changed.

In various embodiments, the common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F to the second structure 1100S. The bit lines BL may be electrically connected to the page buffer 1120 through second connection lines 1125, which are extended from the first structure 1100F to the second structure 1100S.

In the first structure 1100F, the decoder circuit 1110 and the page buffer 1120 may execute a control operation on at least one memory cell transistor that is selected from the memory cell transistors MCT, where the memory cell transistors MCT may be in the second structure 1100S. The decoder circuit 1110 and the page buffer 1120 may be controlled by the logic circuit 1130. The three-dimensional semiconductor memory device 1100 may communicate with the controller 1200 through an input/output pad 1101, which may be electrically connected to the logic circuit 1130. The input/output pad 1101 may be electrically connected to the logic circuit 1130 through an input/output connection line 1135, which is extended from the first structure 1100F to the second structure 1100S.

In various embodiments, the first structure 1100F may further include a voltage generator. The voltage generator may generate a program voltage, a read voltage, a pass voltage, a verification voltage, and so forth, which are used to operate the memory cell strings CSTR. The program voltage may be a relatively high voltage (e.g., 20V to 40V), compared with the read voltage, the pass voltage, and the verification voltage.

In various embodiments, the first structure 1100F may include high voltage transistors and low voltage transistors. The decoder circuit 1110 may include pass transistors, which are connected to the word lines WL of the memory cell strings CSTR. The pass transistors may include high-voltage transistors, which can stand a high voltage (e.g., the program voltage) applied to the word lines WL during a programming operation). The page buffer 1120 may also include high-voltage transistors which can stand the high voltage.

In various embodiments, the controller 1200 may include a processor 1210, a NAND controller 1220, and a host interface 1230. In an embodiment, a plurality of three-dimensional semiconductor memory devices 1100 may be provided, and the controller 1200 may be configured to control the three-dimensional semiconductor memory devices 1100.

In various embodiments, the processor 1210 may control overall operations of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, where the NAND interface 1221 may be used for communication with the three-dimensional semiconductor memory device 1100. The NAND interface 1221 may be used to transmit and receive control commands, which can be used to control the three-dimensional semiconductor memory device 1100 and data, which will be written in or read from the memory cell transistors MCT. The host interface 1230 may be configured to allow for communication between the electronic system 1000 and an external host. If a control command is provided from an external host through the host interface 1230, the processor 1210 may control the three-dimensional semiconductor memory device 1100 in response to the control command.

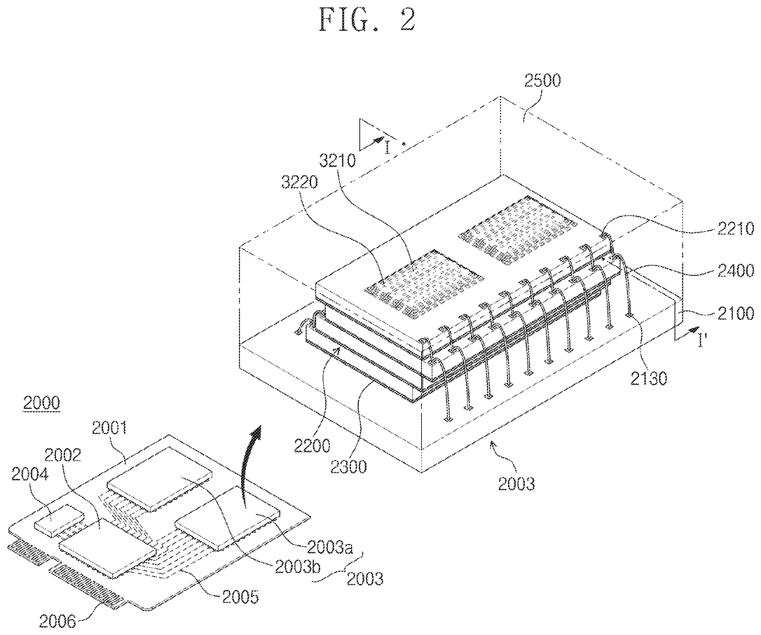

FIG. 2 is a perspective view schematically illustrating an electronic system including a three-dimensional semiconductor memory device, according to an embodiment of the inventive concept.

Referring to FIG. 2, an electronic system 2000 may include a main substrate 2001 and a controller 2002, one or more semiconductor packages 2003, and a DRAM 2004, which are mounted on the main substrate 2001. The semiconductor package 2003, the DRAM 2004, and the controller 2002 may be connected to each other through interconnection patterns 2005, which are formed in the main substrate 2001.

In various embodiments, the main substrate 2001 may include a connector 2006, which can include a plurality of pins coupled to an external host. In the connector 2006, the number and the arrangement of the pins may be changed depending on a communication interface between the electronic system 2000 and the external host, where for example, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In an embodiment, the electronic system 2000 may be driven by electric power that is supplied from the external host through the connector 2006. The electronic system 2000 may further include a power management integrated circuit (PMIC) that may be used to separately supply the electric power, which is provided from the external host, to the controller 2002 and the semiconductor package 2003.

The controller 2002 may control a writing or reading operation on the semiconductor package 2003 and may improve an operation speed of the electronic system 2000.

In various embodiments, the DRAM 2004 may be a buffer memory that is used to handle a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

In various embodiments, the semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

In various embodiments, the package substrate 2100 may be a printed circuit board including upper pads 2130. Each of the semiconductor chips 2200 may include an input/output pad 2210, where the input/output pad 2210 may correspond to the input/output pad 1101 of FIG. 1. Each of the semiconductor chips 2200 may include stacks 3210 and vertical structures 3220. Each of the semiconductor chips 2200 may include a three-dimensional semiconductor memory device, which will be described below.

In various embodiments, the connection structure 2400 may be a bonding wire electrically connecting the input/output pad 2210 to the upper pads 2130, where in each of the first and second semiconductor packages 2003a and 2003b, the semiconductor chips 2200 may be electrically connected to each other in a bonding wire manner and may be electrically connected to the upper pads 2130 of the package substrate 2100. In an embodiment, the semiconductor chips 2200 in each of the first and second semiconductor packages 2003a and 2003b may be electrically connected to each other by a connection structure including through silicon vias (TSVs), rather than the connection structure 2400 provided in the form of bonding wires.

In an embodiment, the controller 2002 and the semiconductor chips 2200 may be included in a single package, but the inventive concept is not limited thereto. For example, the controller 2002 and the semiconductor chips 2200 may be mounted on a separate interposer substrate, and may be connected to each other through interconnection lines, which are provided in the interposer substrate.

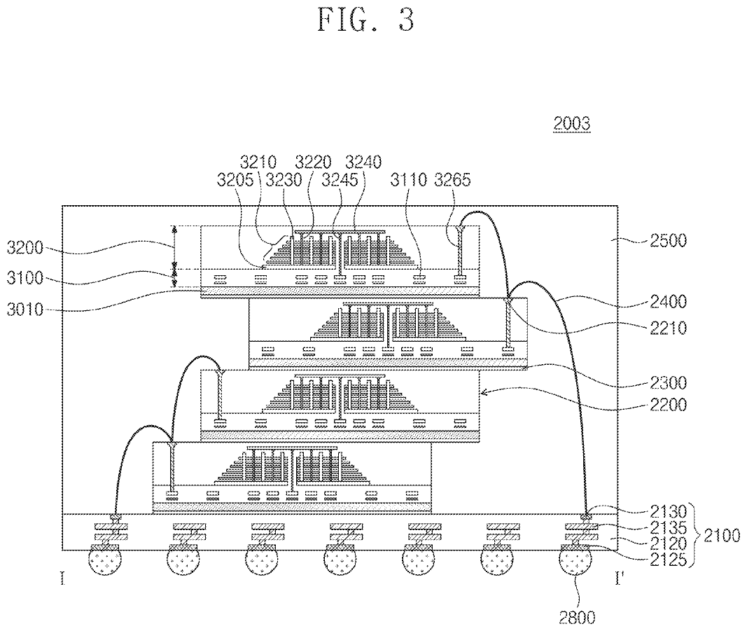

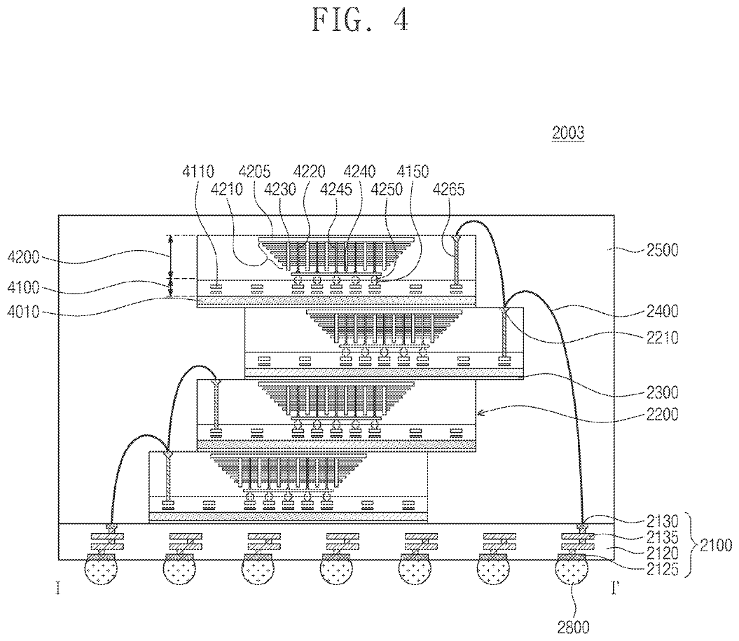

FIGS. 3 and 4 are sectional views, which are taken along a line I-I′ of FIG. 2 to illustrate a semiconductor package including a three-dimensional semiconductor memory device, according to an embodiment of the inventive concept.

Referring to FIG. 3, the package substrate 2100 of the semiconductor package 2003 may be a printed circuit board. The package substrate 2100 may include a package substrate body portion 2120, the upper pads 2130 disposed on a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 of FIG. 2 through conductive connecting portions 2800.

In various embodiments, each of the semiconductor chips 2200 may include a semiconductor substrate 3010 and a first structure 3100 and a second structure 3200, which are sequentially stacked on the semiconductor substrate 3010. The first structure 3100 may include a peripheral circuit region, in which peripheral lines 3110 are provided. The second structure 3200 may include a source structure 3205, a stack 3210 on the source structure 3205, vertical structures 3220 and separation structures 3230, which are provided to penetrate the stack 3210, and bit lines 3240, which are electrically connected to the vertical structures 3220.

In various embodiments, each of the semiconductor chips 2200 may include penetration lines 3245, which are electrically connected to the peripheral lines 3110 of the first structure 3100 and are extended into the second structure 3200. The penetration lines 3245 may be located outside the stack 3210 and may extend through the stack 3210. Each of the semiconductor chips 2200 may include an input/output connection line 3265, which is electrically connected to the peripheral lines 3110 of the first structure 3100 and extends into the second structure 3200, and an input/output pad 2210 electrically connected to the input/output connection line 3265.

Referring to FIG. 4, the semiconductor chips 2200 of the semiconductor package 2003 may include a semiconductor substrate 4010, a first structure 4100 on the semiconductor substrate 4010, and a second structure 4200, which is provided on the first structure 4100 and is bonded to the first structure 4100 in a wafer bonding manner.

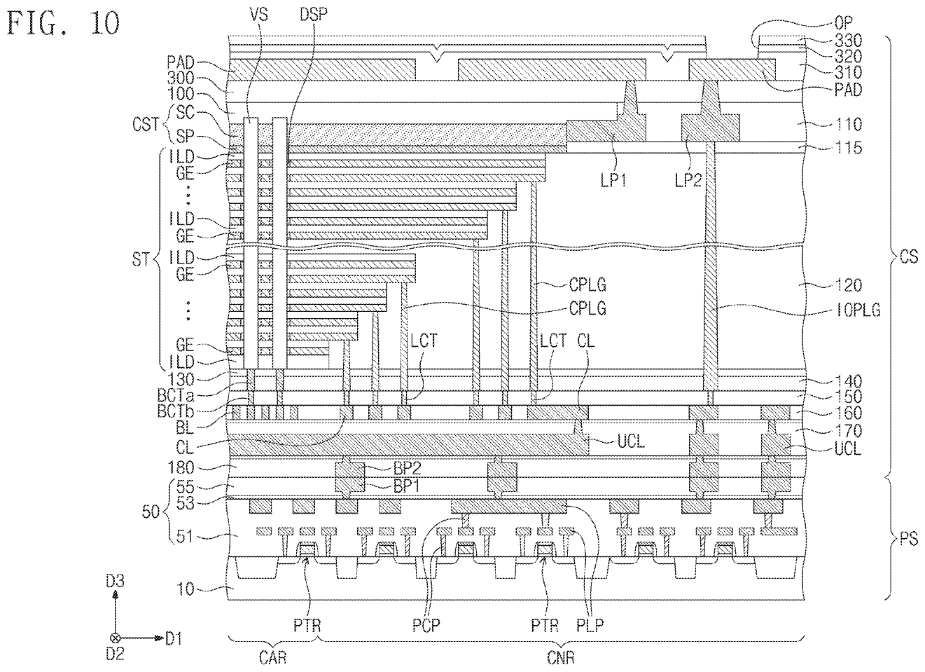

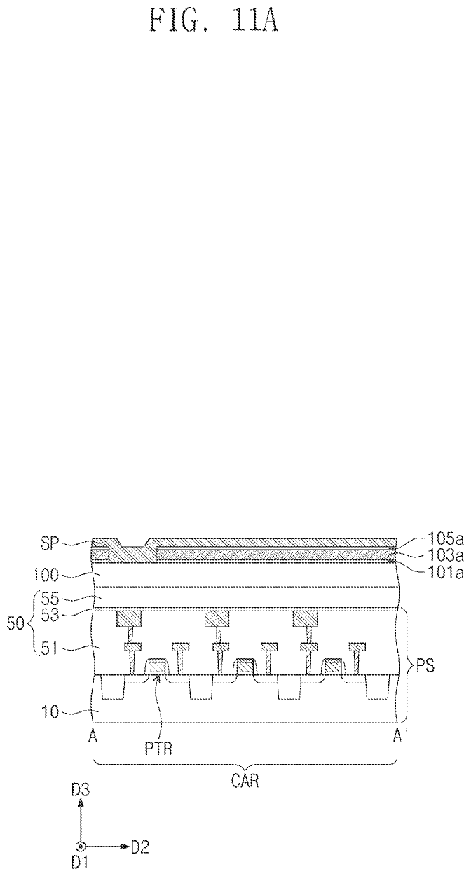

In various embodiments, the first structure 4100 may include a peripheral circuit region, in which a peripheral line 4110 and first junction structures 4150 are provided. The second structure 4200 may include a source structure 4205, a stack 4210, which is provided between the source structure 4205 and the first structure 4100, vertical structures 4220 and a separation structure 4230, which penetrate the stack 4210, and second junction structures 4250, which are electrically and respectively connected to the vertical structures 4220 and the word lines WL (e.g., see FIG. 1) of the stack 4210. In an embodiment, the second junction structures 4250 may be electrically connected to the vertical structures 4220 and the word lines WL (e.g., see FIG. 10). The first junction structures 4150 of the first structure 4100 and the second junction structures 4250 of the second structure 4200 may be bonded to each other and may be in contact with each other. For example, the first junction structures 4150 and the second junction structures 4250 may be formed of or include copper (Cu).

In various embodiments, each of the semiconductor chips 2200 may include an input/output connection line 4265, which is electrically connected to the peripheral lines 4110 of the first structure 4100 and extends into the second structure 4200, and an input/output pad 2210 electrically connected to the input/output connection line 4265.

Referring back to FIGS. 3 and 4, the first structure 3100 or 4100 and the second structure 3200 or 4200 may correspond to the first and second structures 1100F and 1100S of FIG. 1. The semiconductor chips 2200 may be electrically connected to each other by the connection structures 2400, which are provided in the form of bonding wires, but the inventive concept is not limited thereto. For example, the semiconductor chips 2200 may be electrically connected to each other by penetration electrodes penetrating the semiconductor chips 2200.

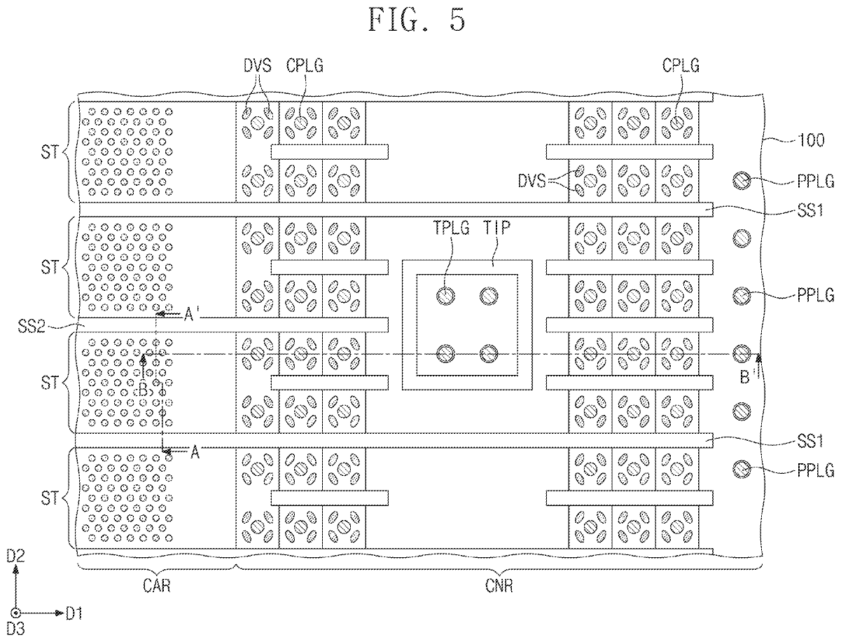

FIG. 5 is a plan view illustrating a three-dimensional semiconductor memory device, according to an embodiment of the inventive concept.

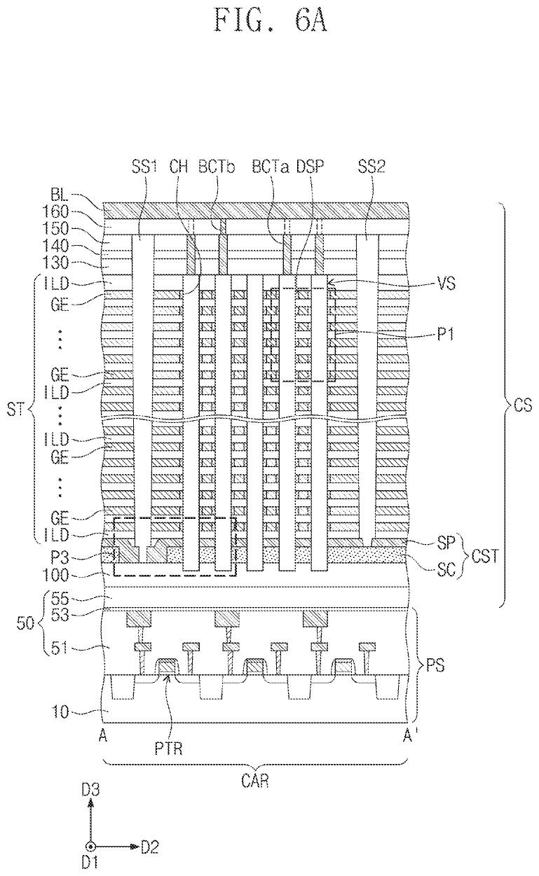

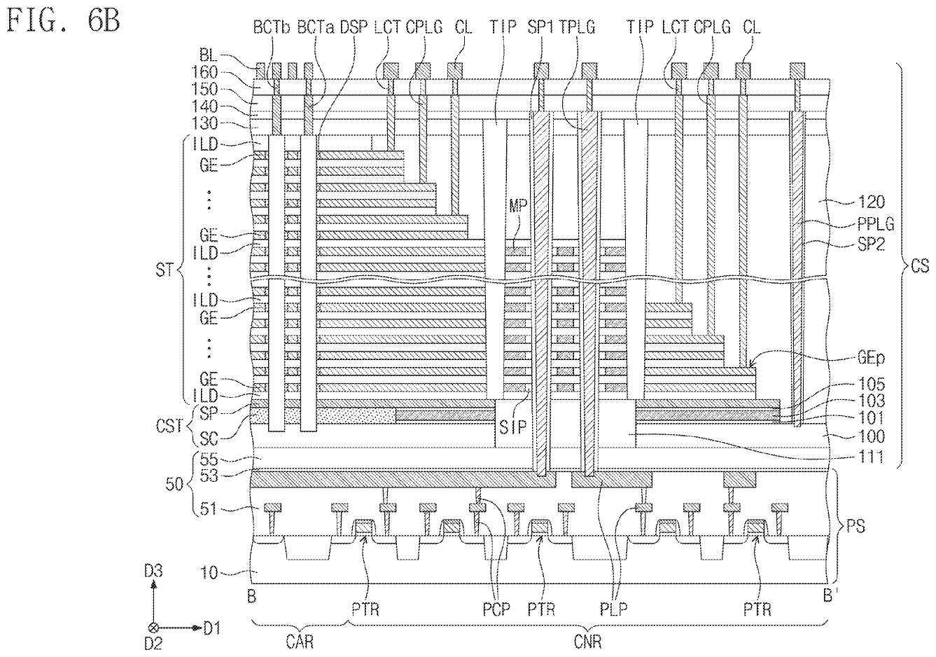

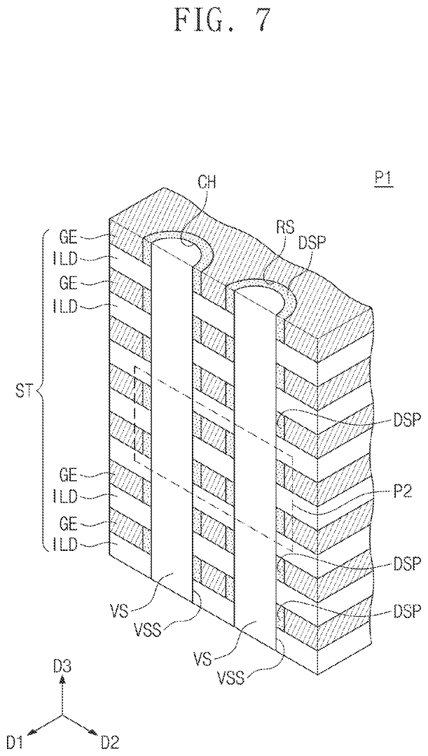

FIGS. 6A and 6B are sectional views, which are respectively taken along lines A-A′ and B-B′ of FIG. 5 to illustrate a three-dimensional semiconductor memory device according to an embodiment of the inventive concept.

Referring to FIGS. 5, 6A, and 6B, a three-dimensional semiconductor memory device according to an embodiment of the inventive concept may include a peripheral circuit structure PS and a cell array structure CS on the peripheral circuit structure PS. For example, the peripheral circuit structure PS may correspond to the first structures 1100F, 3100, and 4100 of FIGS. 1, 3, and 4, and the cell array structure CS may correspond to the second structures 1100S, 3200, and 4200 of FIGS. 1, 3, and 4.

In various embodiments, the peripheral circuit structure PS may include a first substrate 10, peripheral circuits PTR integrated on the first substrate 10, and a lower insulating layer 50 covering the peripheral circuits PTR.

In various embodiments, the first substrate 10 may include a cell array region CAR and a connection region CNR, as shown e.g., in FIG. 6B. The first substrate 10 may be extended in a first direction D1 from the cell array region CAR toward the connection region CNR and in the second direction D2 crossing the first direction D1. The first and second directions D1 and D2 may be parallel to a top surface of the first substrate 10, and a third direction D3 may be orthogonal to the first and second directions D1 and D2. In an embodiment, the first, second, and third directions D1, D2, and D3 may be orthogonal to each other.

When viewed in a plan view, the connection region CNR may be extended from the cell array region CAR to the first direction D1. Vertical channel structures VS and bit lines BL, which are electrically connected to each other, may be provided on the cell array region CAR, as shown e.g., in FIG. 6A. Pad portions GEp and cell contact plugs CPLG, which are connected to each other, as shown e.g., in FIG. 6B, may be provided on the connection region CNR, where the pad portions GEp may be provided to form a stepwise structure, as will be described below.

In various embodiments, the first substrate 10 may be a silicon substrate, a silicon-germanium substrate, a germanium substrate, or a single-crystalline epitaxial layer grown on a single-crystalline silicon substrate.

In various embodiments, a device isolation layer may be provided in the first substrate 10 to define an active region, and the peripheral circuits PTR may be placed on the active region. In an embodiment, the peripheral circuits PTR may include row and column decoders, a page buffer, and a control circuit. The peripheral circuits PTR may include NMOS and PMOS transistors. Peripheral circuit lines PLP may be electrically connected to the peripheral circuits PTR through peripheral contact plugs PCP. The peripheral circuit lines PLP may correspond to the peripheral lines 3110 and 4110 of FIGS. 3 and 4.

In various embodiments, the lower insulating layer 50 may be provided on the first substrate 10 to cover the peripheral circuits PTR, the peripheral contact plugs PCP, and the peripheral circuit lines PLP. The lower insulating layer 50 may include a first lower insulating layer 51, a second lower insulating layer 55, and an etch stop layer 53 between the first and second lower insulating layers 51 and 55. The etch stop layer 53 may include an insulating material different from the first and second lower insulating layers 51 and 55. The etch stop layer 53 may be between the second lower insulating layer 55 and the peripheral circuit lines PLP, and may cover top surfaces of the uppermost ones of the peripheral circuit lines PLP. For example, the lower insulating layer 50 may be formed at least one of silicon oxide, silicon nitride, silicon oxynitride, and/or low-k dielectric materials.

In various embodiments, the cell array structure CS may include a second substrate 100, a source structure CST, a stack ST, vertical channel structures VS, data storage patterns DSP, dummy vertical structures DVS, cell contact plugs CPLG, penetration contact plugs TPLG, bit lines BL, and conductive lines CL.

In various embodiments, the second substrate 100 may be provided on a top surface of the lower insulating layer 50, where the second substrate 100 may be on a top surface of the second lower insulating layer 55. The second substrate 100 may be formed of or include semiconductor materials, insulating materials, conductive materials, or a combination thereof. The second substrate 100 may be formed of or include a semiconductor material, which is doped with impurities of a first conductivity type (e.g., n-type), and/or an undoped (i.e., intrinsic) semiconductor material. The second substrate 100 may have at least one of single crystalline, amorphous, or polycrystalline structures.

In various embodiments, the source structure CST may be provided between the second substrate 100 and the stack ST, as shown e.g., in FIG. 6B. The source structure CST may be parallel to a top surface of the second substrate 100 and may be extended parallel to the stack ST or in the first direction D1, in the cell array region CAR. The source structure CST may correspond to the common source line CSL of FIG. 1 or the source structures 3205 and 4205 of FIGS. 3 and 4.

In various embodiments, the source structure CST may include a source conductive pattern SC and a support conductive pattern SP on the source conductive pattern SC. In the cell array region CAR, the source conductive pattern SC may be disposed between the second substrate 100 and the stack ST. In the cell array region CAR, the source conductive pattern SC may have an opening exposing the top surface of the second substrate 100. The opening of the source conductive pattern SC may have a circular or bar shape, and in an embodiment, a plurality of openings may be provided. In an embodiment, the source conductive pattern SC may be formed of or include a semiconductor material that is doped with impurities of a first conductivity type.

In the connection region CNR, dummy insulating patterns 101, 103, and 105 may be provided between the second substrate 100 and the stack ST. The dummy insulating patterns 101, 103, and 105 may be located at substantially the same level as the source conductive pattern SC.

In various embodiments, the dummy insulating patterns 101, 103, and 105 may include a first dummy insulating pattern 101, a second dummy insulating pattern 103, and a third dummy insulating pattern 105 that are sequentially stacked. The second dummy insulating pattern 103 may be formed of or include an electrically insulating material different from the first and third dummy insulating patterns 101 and 105. The second dummy insulating pattern 103 may be thicker than the first and third dummy insulating patterns 101 and 105. The first, second, and third dummy insulating patterns 101, 103, and 105 may be formed of or include at least one of silicon oxide, silicon nitride, silicon oxynitride, silicon carbide, or silicon germanium.

In various embodiments, in the cell array region CAR, the support conductive pattern SP may cover a top surface of the source conductive pattern SC and may fill a portion of the opening of the source conductive pattern SC. Thus, the support conductive pattern SP may have a recessed top surface, in the opening of the source conductive pattern SC. In the connection region CNR, the support conductive pattern SP may cover the top surfaces of the dummy insulating patterns 101, 103, and 105, where the support conductive pattern SP extends into the connection region CNR. In an embodiment, the support conductive pattern SP may be formed of or include a semiconductor material, which is doped with impurities of a first conductivity type (e.g., n-type), and/or an undoped (i.e., intrinsic) semiconductor material.

In the connection region CNR, a mold insulating pattern 111 may be provided, where the mold insulating pattern 111 may extend through the support conductive pattern SP, the dummy insulating patterns 101, 103, and 105, and the second substrate 100. The mold insulating pattern 111 may be in contact with the lower insulating layer 50 and may have a top surface that is substantially coplanar with a top surface of the support conductive pattern SP.

In various embodiments, the stack ST may be provided on the source structure CST. The stack ST may extend from the cell array region CAR to the connection region CNR in the first direction D1. In an embodiment, a plurality of stacks ST may be spaced apart from each other in the second direction D2. The stack ST may correspond to the stacks 3210 and 4210 of FIGS. 3 and 4.

In various embodiments, the stack ST may include gate electrodes GE and insulating layers ILD, which are alternately stacked in a third direction D3 (e.g., a vertical direction), where the third direction D3 may be perpendicular to first and second directions D1 and D2 crossing each other. In the connection region CNR, the gate electrodes GE may have pad portions GEp. The pad portions GEp of the gate electrodes GE may be placed at different positions in horizontal and vertical directions. For example, the stack ST may have a stepwise structure in the connection region CNR.

In various embodiments, each of the gate electrodes GE may have substantially the same thickness in the third direction D3. The insulating layers ILD may have different thicknesses from each other in the third direction D3. For example, when measured in the third direction D3, a thickness of the uppermost one of the insulating layers ILD may be larger than thicknesses of the remaining ones of the insulating layers ILD, and the remaining ones of the insulating layers ILD may have substantially the same thickness.

In various embodiments, the lengths of the gate electrodes GE in the first direction D1 may decrease as a distance from the second substrate 100 in the third direction D3 increases. For example, the uppermost one of the gate electrodes GE may have the shortest length in the first direction D1, and the lowermost one of the gate electrodes GE may have the largest length in the first direction D1. Similar to the gate electrodes GE, lengths of the insulating layers ILD in the first direction D1 may decrease as a distance from the second substrate 100 in the third direction D3 increases. In an embodiment, the side surface of each of the insulating layers ILD may be aligned to a side surface of one of the gate electrodes GE adjacent thereto, where the insulating layer ILD and the gate electrode GE having substantially the same length can form a step in the third direction D3.

In various embodiments, the gate electrodes GE may be formed of or include at least one of, for example, doped semiconductor materials (e.g., doped silicon), metallic materials (e.g., tungsten, copper, or aluminum), conductive metal nitrides (e.g., titanium nitride or tantalum nitride), or transition metals (e.g., titanium or tantalum). The insulating layers ILD may be formed of or include at least one of silicon oxide, silicon nitride, silicon oxynitride, low-k dielectric materials, high density plasma (HDP) oxide, and/or tetraethyl orthosilicate (TEOS). In an embodiment, the three-dimensional semiconductor memory device may be a vertical-type NAND FLASH memory device, and the gate electrodes GE of the stack ST may correspond to the gate lower lines LL1 and LL2, the word lines WL, and gate upper lines UL1 and UL2 of FIG. 1.

In the connection region CNR, the stack ST may include mold patterns MP and sidewall insulating patterns SIP. Between the insulating layers ILD, each of the mold patterns MP and the sidewall insulating patterns SIP may be located at the same level as the gate electrodes GE. The mold patterns MP may be placed between the pad portions GEp of the gate electrodes GE. The sidewall insulating patterns SIP may be placed between the mold patterns MP and the penetration contact plugs TPLG. The sidewall insulating patterns SIP may be provided to enclose portions of the side surfaces of the penetration contact plugs TPLG. When viewed in a plan view, the mold patterns MP and the sidewall insulating patterns SIP may be overlapped with the mold insulating pattern 111. The mold patterns MP may be formed of or include an electrically insulating material different from the insulating layers ILD. The sidewall insulating patterns SIP may be formed of or include an electrically insulating material different from the mold patterns MP. The mold patterns MP may be formed of or include at least one of silicon nitride, silicon oxynitride, or silicon germanium, and the sidewall insulating patterns SIP may be formed of or include silicon oxide.

In an embodiment, the stack ST may include a first stack and a second stack on the first stack. The first stack may include first gate electrodes and first insulating layers, which are alternately stacked on the second substrate 100 in the third direction D3. The second stack may include second gate electrodes and second insulating layers, which are alternately stacked on the first stack in the third direction D3. The uppermost one of the first insulating layers may be in contact with the lowermost one of the second insulating layers.

In the cell array region CAR, the vertical channel structures VS may penetrate the stack ST and the source structure CST, as shown e.g., in FIG. 6A. The vertical channel structures VS may penetrate a portion of the second substrate 100 and may be in contact with the second substrate 100. For example, a bottom surface of each of the vertical channel structures VS may be located at a level lower than the top surface of the second substrate 100 and the bottom surface of the source structure CST.

When viewed in a plan view, the vertical channel structures VS may be arranged to form a zigzag shape in the first or second direction D1 or D2. The vertical channel structures VS may not be provided on the connection region CNR. The vertical channel structures VS may correspond to the vertical structures 3220 and 4220 of FIGS. 3 and 4 and may correspond to channel regions of the lower transistors LT1 and LT2, the upper transistors UT1 and UT2, and the memory cell transistors MCT of FIG. 1.

In various embodiments, a width of each of the vertical channel structures VS in the first or second direction D1 or D2 may increase as a height in the third direction D3 increases. For example, in each of the vertical channel structures VS, a width of the uppermost portion may be larger than a width of the lowermost portion. However, the inventive concept is not limited to this example, and each of the vertical channel structures VS in the first or second direction D1 or D2 may have a constant width, regardless of a height in the third direction D3.

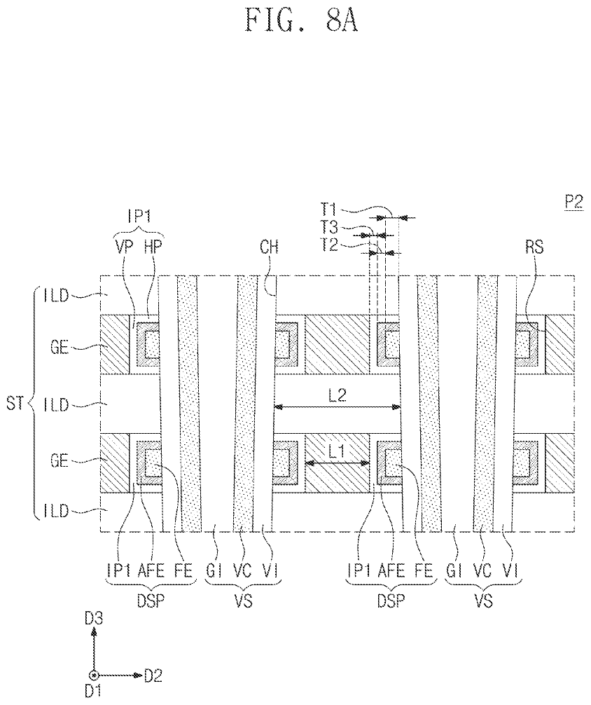

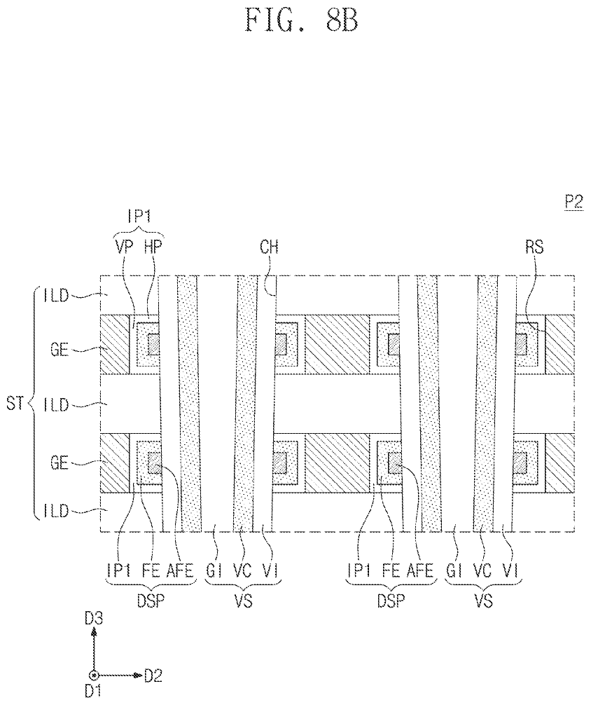

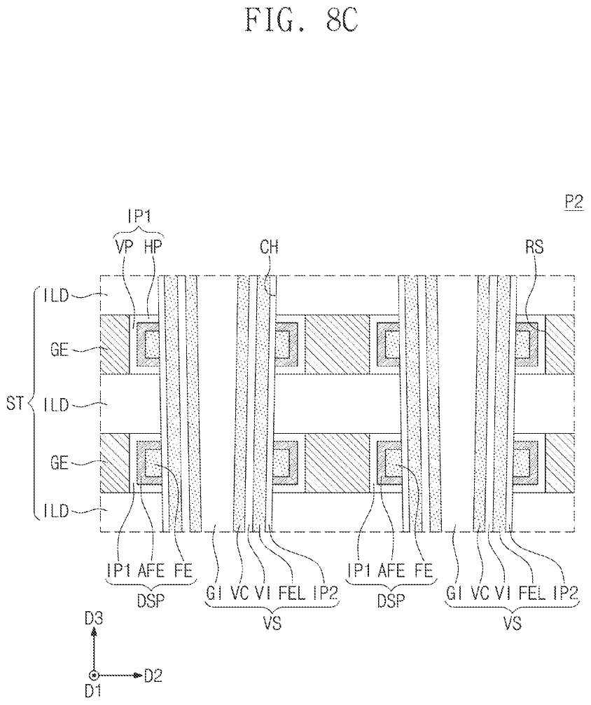

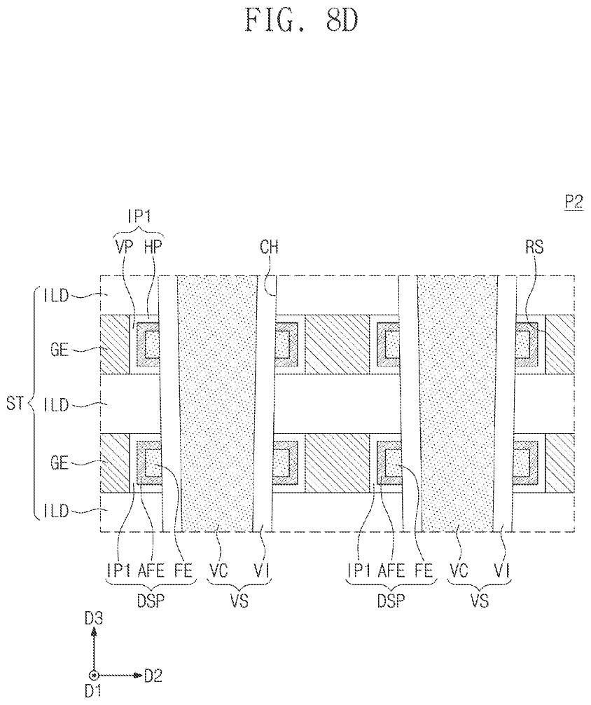

In various embodiments, the data storage patterns DSP may be provided between the stack ST and the vertical channel structures VS. The data storage patterns DSP may be placed on the cell array region CAR and may not be extended to the connection region CNR, where the data storage patterns DSP may be absent in the connection region CNR. The data storage patterns DSP will be described in more detail with reference to FIGS. 7 and 8A to 8D.

In the connection region CNR, a planarization insulating layer 120 may be provided on the stack ST, as shown e.g., in FIG. 6B. The planarization insulating layer 120 may cover the stepwise structure of the stack ST. The planarization insulating layer 120 may be located on the pad portions GEp of the gate electrodes GE. The planarization insulating layer 120 may have a substantially flat top surface, where the top surface of the planarization insulating layer 120 may be coplanar with the top surface of the stack ST. The top surface of the planarization insulating layer 120 may be located at the same level as a top surface of the uppermost one of the insulating layers ILD and top surfaces of the vertical channel structures VS. In an embodiment, the planarization insulating layer 120 may include a single insulating layer or a plurality of stacked insulating layers.

In various embodiments, a first interlayer insulating layer 130 may be provided on the planarization insulating layer 120 and the stack ST. The first interlayer insulating layer 130 may cover the top surfaces of the vertical channel structures VS.

In various embodiments, in the connection region CNR, a penetration insulating pattern TIP may be provided to penetrate the first interlayer insulating layer 130, the planarization insulating layer 120, and the stack ST. The penetration insulating pattern TIP may be placed between the gate electrodes GE and the mold patterns MP. When viewed in a plan view, the penetration insulating pattern TIP may enclose the mold patterns MP. The penetration insulating pattern TIP may include an insulating layer that is provided to cover a side surface of the stack ST and side surfaces of the mold patterns MP. The penetration insulating pattern TIP may be in contact with the support conductive pattern SP and the penetration insulating pattern TIP.

In various embodiments, a second interlayer insulating layer 140 may be provided on the first interlayer insulating layer 130. The second interlayer insulating layer 140 may cover a top surface of the first interlayer insulating layer 130 and a top surface of the penetration insulating pattern TIP. A thickness of the second interlayer insulating layer 140 may be less than a thickness of the first interlayer insulating layer 130. The second interlayer insulating layer 140 may be formed of or include an electrically insulating material different from the first interlayer insulating layer 130.

In the connection region CNR, the penetration contact plugs TPLG may be provided to penetrate the first and second interlayer insulating layers 130 and 140, the planarization insulating layer 120, the stack ST, and the mold insulating pattern 111. The penetration contact plugs TPLG may be connected to the peripheral circuit lines PLP of the peripheral circuit structure PS. When viewed in a plan view, the penetration contact plugs TPLG may be placed inside the penetration insulating pattern TIP. A first spacer SP1 may be provided to enclose a side surface of each of the penetration contact plugs TPLG, where the first spacer SP1 may be formed of or include an electrically insulating material.

In various embodiments, in the connection region CNR, peripheral contact plugs PPLG may be provided to penetrate the first and second interlayer insulating layers 130 and 140 and the planarization insulating layer 120. The peripheral contact plugs PPLG may be connected to the second substrate 100. The peripheral contact plugs PPLG may be spaced apart from the stack ST in the first direction D1. Alternatively, the peripheral contact plugs PPLG may be electrically connected to the support conductive pattern SP of the source structure CST. Top surfaces of the peripheral contact plugs PPLG may be coplanar with top surfaces of the penetration contact plugs TPLG. A second spacer SP2 may be provided to enclose a side surface of each of the peripheral contact plugs PPLG, and here, the second spacer SP2 may be formed of or include an electrically insulating material.

In various embodiments, a third interlayer insulating layer 150 may be provided on the second interlayer insulating layer 140. The third interlayer insulating layer 150 may cover the top surfaces of the penetration contact plugs TPLG and the top surfaces of the peripheral contact plugs PPLG.

In various embodiments, first and second separation structures SS1 and SS2 may be provided on the second substrate 100 to penetrate the first to third interlayer insulating layers 130, 140, and 150 and the stack ST, as shown e.g., in FIG. 6A. Each of the first and second separation structures SS1 and SS2 may include an insulating layer covering the side surface of the stack ST. Each of the first and second separation structures SS1 and SS2 may include a single layer or may have a multi-layered structure. Top surfaces of the first and second separation structures SS1 and SS2 may be positioned at substantially the same level.

In various embodiments, the first separation structures SS1 may be extended from the cell array region CAR to the connection region CNR in the first direction D1. The first separation structures SS1 may be spaced apart from each other in the second direction D2. The first separation structures SS1 may penetrate the support conductive pattern SP filling the opening of the source conductive pattern SC. The first separation structures SS1 may be in contact with the second substrate 100.

In various embodiments, the second separation structure SS2 may extend from the cell array region CAR to the connection region CNR in the first direction D1. The second separation structure SS2 may be disposed between the first separation structures SS1. A length of the second separation structure SS2 in the first direction D1 may be less than lengths of the first separation structures SS1 in the first direction D1. Because the second separation structure SS2 is placed on the source conductive pattern SC, a vertical length of the second separation structure SS2 may be less than vertical lengths of the first separation structures SS1.

In various embodiments, in the connection region CNR, the cell contact plugs CPLG may be provided to penetrate the first to third interlayer insulating layers 130, 140, and 150 and the planarization insulating layer 120. When viewed in a plan view, each of the cell contact plugs CPLG may be positioned adjacent to the dummy vertical structures DVS. Each of the cell contact plugs CPLG may be connected to a corresponding one of the pad portions GEp of the gate electrodes GE. Top surfaces of the cell contact plugs CPLG may be positioned at substantially the same level. Because the stack ST has the stepwise structure, vertical lengths of the cell contact plugs CPLG may decrease as a distance to the cell array region CAR decreases.

In various embodiments, in the cell array region CAR, first bit line contact plugs BCTa may be provided to penetrate the first to third interlayer insulating layers 130, 140, and 150. Each of the first bit line contact plugs BCTa may be electrically connected to a corresponding one of the vertical channel structures VS.

In various embodiments, a fourth interlayer insulating layer 160 may be provided on the third interlayer insulating layer 150. The fourth interlayer insulating layer 160 may cover the top surfaces of the cell contact plugs CPLG and top surfaces of the first bit line contact plugs BCTa.

In the cell array region CAR, second bit line contact plugs BCTb may be provided to penetrate the fourth interlayer insulating layer 160. Each of the second bit line contact plugs BCTb may be placed on and electrically connected to a corresponding one of the first bit line contact plugs BCTa.

In the connection region CNR, contact plugs LCT may be provided to penetrate the fourth interlayer insulating layer 160. Each of the contact plugs LCT may be placed on and electrically connected to a corresponding one of the cell contact plugs CPLG. Some of the contact plugs LCT may be provided to penetrate the third and fourth interlayer insulating layers 150 and 160. The contact plugs LCT may be electrically connected to the penetration contact plugs TPLG and the peripheral contact plugs PPLG.

In the cell array region CAR, the bit lines BL may be provided on the fourth interlayer insulating layer 160. The bit lines BL may extend in the second direction D2 and may be spaced apart from each other in the first direction D1. Each of the bit lines BL may be connected to a corresponding one of bit line contact plugs BCTa and BCTb. Thus, the bit lines BL may be electrically connected to the vertical channel structures VS via the bit line contact plugs BCTa and BCTb.

In the connection region CNR, the conductive lines CL may be provided on the fourth interlayer insulating layer 160. The conductive lines CL may be spaced apart from each other in the first direction D1. Each of the conductive lines CL may be electrically connected to a corresponding one of the contact plugs LCT. Thus, the conductive lines CL may be electrically connected to the cell contact plugs CPLG, the penetration contact plugs TPLG, and the peripheral contact plugs PPLG through the contact plugs LCT.

FIG. 7 is an enlarged perspective view illustrating a portion (e.g., P1 of FIG. 6A) of a three-dimensional semiconductor memory device, according to an embodiment of the inventive concept. FIGS. 8A to 8D are enlarged sectional views illustrating a portion P2 of FIG. 7. Referring to FIG. 7, recess regions RS may be provided between the stack ST and the vertical channel structures VS, where the recess regions RS are placed in channel holes CH. The recess region RS may be a region recessed from an inner side surface of the channel hole CH in a horizontal direction (e.g., the first and second directions D1 and D2). Each of the recess regions RS may be located at the same level as a corresponding one of the gate electrodes GE of the stack ST and between the insulating layers ILD. The recess regions RS may be spaced apart from each other in the third direction D3, where adjacent recess regions RS may be separated by the insulating layers ILD of the stack ST. The recess regions RS may be provided on side surfaces VSS of the vertical channel structures VS to enclose portions of the side surfaces VSS of the vertical channel structures VS.

Because each of the data storage patterns DSP can be provided in a corresponding one of the recess regions RS, the data storage patterns DSP may be placed between the stack ST and the vertical channel structures VS. The data storage patterns DSP may be placed on the side surfaces VSS of the vertical channel structures VS. The data storage patterns DSP may be in partial contact with the side surfaces VSS of the vertical channel structures VS and may enclose portions of the side surfaces VSS of the vertical channel structures VS. When viewed in a plan view, the data storage patterns DSP may have a ring shape.

In various embodiments, the data storage patterns DSP, which are adjacent to each other in the third direction D3, may be vertically overlapped with each other and may be in common contact with a specific one of the vertical channel structures VS. The data storage patterns DSP, which are adjacent to each other in the second direction D2, may be placed at the same level and may be in contact with different ones of the vertical channel structures VS. Each of the insulating layers ILD may be located between the data storage patterns DSP, which are adjacent to each other in the third direction D3, and the gate electrodes GE may be located between the data storage patterns DSP, which are adjacent to each other in the second direction D2. When viewed in a plan view, the data storage patterns DSP may be partially overlapped with the insulating layers ILD, and the gate electrodes GE may enclose the data storage patterns DSP, where the data storage patterns DSP may surround the vertical channel structures VS. For example, the data storage patterns DSP may be vertically overlapped with portions of the insulating layers ILD.

Referring to FIGS. 7 and 8A, each of the data storage patterns DSP may include a ferroelectric pattern FE adjacent to the vertical channel structures VS, a first insulating pattern IP1 adjacent to the gate electrodes GE, and an anti-ferroelectric pattern AFE between the ferroelectric pattern FE and the first insulating pattern IP1.

In various embodiments, the ferroelectric pattern FE may be placed between the anti-ferroelectric pattern AFE and the vertical channel structures VS. The ferroelectric pattern FE may be in contact with the anti-ferroelectric pattern AFE and the vertical channel structures VS. The ferroelectric pattern FE may be formed of or include a ferroelectric material, where for example, the ferroelectric pattern FE may be formed of or include one or more hafnium-containing dielectric materials (e.g., HfO₂, HfSiO₂ (Si-doped HfO₂), HfAlO₂ (Al-doped HfO₂), HfSiON, HfZnO, HfZrO₂, ZrO₂, ZrSiO₂, HfZrSiO₂, ZrSiON, LaAIO, HfDyO₂, or HfScO₂).

In various embodiments, the first insulating pattern IP1 may be placed between the gate electrodes GE and the anti-ferroelectric pattern AFE. The first insulating pattern IP1 may include a vertical portion VP and horizontal portions HP and may cover inner surfaces of the recess region RS with a uniform thickness. The vertical portion VP of the first insulating pattern IP1 may cover side surfaces of the gate electrodes GE exposed through the recess region RS. Each of the horizontal portions HP may be extended from opposite end portions of the vertical portion VP to partially cover top and bottom surfaces of the insulating layers ILD exposed by the recess region RS. For example, the first insulating pattern IP1 may have a ‘U’-shaped section. In an embodiment, the first insulating pattern IP1 may be formed of or include one or more electrically insulating materials (e.g., silicon oxide, silicon nitride, silicon oxynitride, and low-k dielectric materials).

Between the ferroelectric pattern FE and the first insulating pattern IP1, the anti-ferroelectric pattern AFE may be in contact with the ferroelectric pattern FE and the first insulating pattern IP1. The anti-ferroelectric pattern AFE may have a uniform thickness, between the ferroelectric pattern FE and the first insulating pattern IP1. Similar to the first insulating pattern IP1, the anti-ferroelectric pattern AFE may have a ‘U’-shaped section rotated 90 degrees. The anti-ferroelectric pattern AFE may be formed of or include one or more anti-ferroelectric materials, where for example, the anti-ferroelectric pattern AFE may be formed of or include at least one of ZrO₂ or HfZrO₂.

In various embodiments, the ferroelectric pattern FE may have a first thickness T1 in the second direction D2. The anti-ferroelectric pattern AFE may have a second thickness T2 in the second direction D2. The first insulating pattern IP1 may have a third thickness T3 in the second direction D2. The ferroelectric pattern FE may be thicker than the anti-ferroelectric pattern AFE and the first insulating pattern IP1. The anti-ferroelectric pattern AFE and the first insulating pattern IP1 may have substantially the same thickness. For example, the first thickness T1 may be greater than the second and third thicknesses T2 and T3, and the second and third thicknesses T2 and T3 may be substantially equal to each other. However, the inventive concept is not limited to this example.

In various embodiments, each of the vertical channel structures VS may include a vertical insulating layer VI, a vertical channel pattern VC, and a gapfill insulating pattern GI, which are sequentially provided on an inner side surface of the channel hole CH, as shown e.g., in FIG. 8A. The vertical insulating layer VI, the vertical channel pattern VC, and the gapfill insulating pattern GI may extend in the third direction D3. The gapfill insulating pattern GI may be provided to fill an internal space, which is enclosed by the vertical channel pattern VC, and the vertical insulating layer VI may be provided to enclose a side surface of the vertical channel pattern VC. The vertical channel pattern VC may be shaped like a hollow empty cylinder. The vertical channel pattern VC may be formed of or include at least one of semiconductor materials (e.g., doped Si, Poly-Si, and SiGe), semiconductor oxide materials (e.g., IGZO, Sn-IGZO, IWO, CuS₂, CuSe₂, WSe₂, IZO, ZTO, and YZO), or two-dimensional materials (e.g., MoS₂, MoSe₂, and WS₂). The vertical channel pattern VC may be used as channel regions of the upper transistors UT1 and UT2, the memory cell transistors MCT, and the lower transistors LT1 and LT2 of FIG. 1.

In various embodiments, the gate electrodes GE of the stack ST may have a first length L1 in the second direction D2, between the vertical channel structures VS which are adjacent to each other in the second direction D2. The insulating layers ILD of the stack ST may have a second length L2 in the second direction D2, between the vertical channel structures VS which are adjacent to each other in the second direction D2. In an embodiment, the first length L1 may be smaller than the second length L2. The data storage patterns DSP may be located between the vertical channel structures VS and the gate electrodes GE at the same level as the gate electrodes GE. Thus, between the vertical channel structures VS, a horizontal length of the gate electrodes GE may be smaller than a horizontal length of the insulating layers ILD.

Referring to FIGS. 7 and 8B, each of the data storage patterns DSP may include the ferroelectric pattern FE located between the first insulating pattern IP1 and the anti-ferroelectric pattern AFE. The ferroelectric pattern FE between the first insulating pattern IP1 and the anti-ferroelectric pattern AFE may be in contact with the first insulating pattern IP1 and the anti-ferroelectric pattern AFE. Between the first insulating pattern IP1 and the anti-ferroelectric pattern AFE, the ferroelectric pattern FE may have a substantially constant thickness. In an embodiment, the ferroelectric pattern FE may have a U-shaped section.

Referring to FIGS. 7 and 8C, each of the vertical channel structures VS may include the gapfill insulating pattern GI, the vertical channel pattern VC, and the vertical insulating layer VI, and in an embodiment, it may further include a ferroelectric layer FEL, and a second insulating pattern IP2.

In various embodiments, the ferroelectric layer FEL may be placed between the second insulating pattern IP2 and the vertical insulating layer VI to cover a side surface of the vertical insulating layer VI, as shown e.g., in FIG. 8C. The ferroelectric layer FEL may be formed of or include a ferroelectric material. The ferroelectric layer FEL may be formed of or include the same ferroelectric material as the ferroelectric pattern FE, but the inventive concept is not limited thereto. For example, the ferroelectric layer FEL may be formed of or include a ferroelectric material different from the ferroelectric pattern FE, where for example, the ferroelectric layer FEL may be formed of or include one or more hafnium-containing dielectric materials (e.g., HfO₂, HfSiO₂ (Si-doped HfO₂), HfAlO₂ (Al-doped HfO₂), HfSiON, HfZnO, HfZrO₂, ZrO₂, ZrSiO₂, HfZrSiO₂, ZrSiON, LaAIO, HfDyO₂, or HfScO₂).

In various embodiments, the second insulating pattern IP2 of the vertical channel structures VS may be provided between the stack ST and the ferroelectric layer FEL to cover a side surface of the ferroelectric layer FEL. The second insulating pattern IP2 may be formed of or include an electrically insulating material. The second insulating pattern IP2 may be formed of or include the same insulating material as the first insulating pattern IP1, but the inventive concept is not limited thereto. For example, the second insulating pattern IP2 may be formed of or include an electrically insulating material different from the first insulating pattern IP1. In an embodiment, the second insulating pattern IP2 may be formed of or include at least one of silicon oxide, silicon nitride, silicon oxynitride, or low-k dielectric materials.

In various embodiments, the second insulating pattern IP2 including an insulating material may be provided between the ferroelectric pattern FE and the ferroelectric layer FEL. An overall electrostatic capacitance between the ferroelectric pattern FE and the ferroelectric layer FEL may be increased. Thus, the electrical characteristics of the three-dimensional semiconductor memory device may be improved.

Referring to FIGS. 7 and 8D, each of the vertical channel structures VS may include the vertical channel pattern VC and the vertical insulating layer VI, which is provided to enclose the side surface of the vertical channel pattern VC. The gapfill insulating pattern GI of FIGS. 8A to 8C may be omitted. The vertical channel pattern VC may have the shape of a pillar. Accordingly, a size of the vertical channel structures VS may be reduced. As a result, it may be possible to reduce a size of a three-dimensional semiconductor memory device.

Referring back to FIGS. 8A to 8D, the ferroelectric pattern FE in the three-dimensional semiconductor memory device, according to an embodiment, may include a ferroelectric material, which has a dipole-induced remnant polarization even when an electric field is absent. A polarization direction of the ferroelectric material may be changed by an external electric field, where a polarization state of the ferroelectric pattern FE can be changed to one of positive and negative polarization states by the external electric field applied to the ferroelectric pattern FE during a programming operation. Because the polarization state of the ferroelectric pattern FE can be maintained even when there is no power supplied to the three-dimensional semiconductor memory device, the three-dimensional semiconductor memory device may serve as a nonvolatile memory device.

In the three-dimensional semiconductor memory device, according to an embodiment, the anti-ferroelectric pattern AFE may include an anti-ferroelectric material exhibiting a double hysteresis loop property. In an embodiment, the anti-ferroelectric material may have an electrostatic capacitance greater than the ferroelectric material, under a relatively strong electric field (e.g., about 2.0 MV/cm or stronger). Because the anti-ferroelectric pattern AFE does not have a remnant polarization when an electric field is absent, the programming operation may be more easily performed, and an overall electrostatic capacitance of the nonvolatile memory device may be increased. As a result, the electrical characteristics of the three-dimensional semiconductor memory device may be improved.

In various embodiments, the first insulating pattern IP1 including an insulating material may be placed between the gate electrodes GE and the ferroelectric pattern FE and may be used to store electric charges. The first insulating pattern IP1 may serve as a charge trap layer of a nonvolatile memory device, where the nonvolatile memory device may have an increased memory window. This can provide a multibit cell. Accordingly, the electrical characteristics of the three-dimensional semiconductor memory device may be improved.

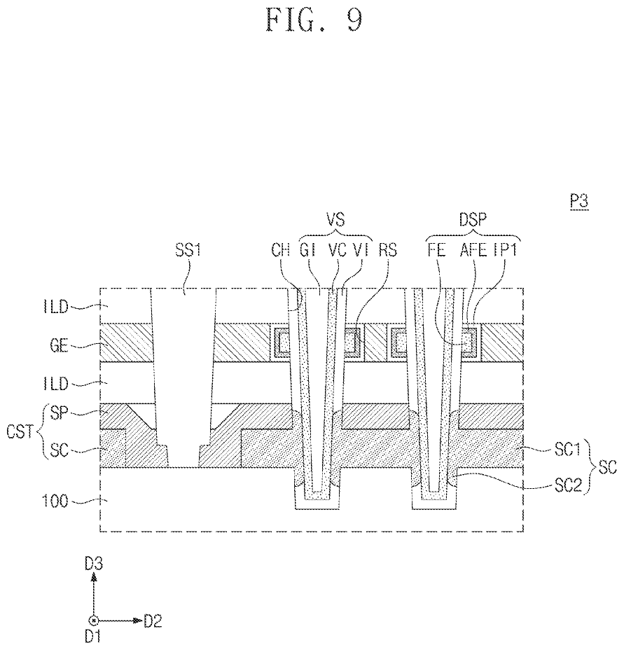

FIG. 9 is an enlarged sectional view illustrating a portion (e.g., P3 of FIG. 6A) of a three-dimensional semiconductor memory device, according to an embodiment of the inventive concept.

Referring to FIG. 9, each of the vertical channel structures VS may include the vertical channel pattern VC and the vertical insulating layer VI enclosing the side surface of the vertical channel pattern VC. The vertical channel pattern VC may be shaped like an annular cylinder (e.g., pipe or macaroni) with a closed bottom. The vertical channel pattern VC may have a ‘U’-shaped section. A bottom surface of the vertical channel pattern VC may be located at a level that is lower than a bottom surface of the source conductive pattern SC and the top surface of the second substrate 100.

In various embodiments, the source conductive pattern SC may include a horizontal portion SC1 and a sidewall portion SC2. The horizontal portion SC1 of the source conductive pattern SC may be between the support conductive pattern SP and the second substrate 100 and parallel to the stack ST. A top surface of the horizontal portion SC1 of the source conductive pattern SC may be in contact with a bottom surface of the support conductive pattern SP, and a bottom surface of the horizontal portion SC1 may be in contact with the top surface of the second substrate 100.

In various embodiments, the sidewall portion SC2 of the source conductive pattern SC may vertically protrude from the horizontal portion SC1, and extend along a portion of a sidewall of the vertical channel pattern VC. The sidewall portion SC2 may be in contact with a portion of the side surface of the vertical channel pattern VC, and may enclose the portion of the side surface of the vertical channel pattern VC. The source conductive pattern SC may be in contact with the vertical channel pattern VC. The sidewall portion SC2 may be in contact with at least a portion of a side surface of the support conductive pattern SP. The sidewall portion SC2 may be in contact with the vertical insulating layer VI, and a surface of the sidewall portion SC2, which is in contact with the vertical insulating layer VI, may have a curved shape. A thickness of the sidewall portion SC2 in the third direction D3 may be greater than a thickness of the horizontal portion SC1 in the third direction D3.

Various three-dimensional semiconductor memory devices, according to various embodiments of the inventive concept, will be described below, and the same or similar elements, as previously described will be identified with the same reference number without repeating the overlapping description.

FIG. 10 is a sectional view illustrating a three-dimensional semiconductor memory device, according to an embodiment of the inventive concept.

Referring to FIG. 10, a semiconductor device, according to an embodiment, may have a chip-to-chip (C2C) structure. For the C2C structure, an upper chip, including the cell array structure CS, may be fabricated on a wafer, and a lower chip, including the peripheral circuit structure PS, may be fabricated on another wafer. The upper chip and the lower chip may be attached to each other through a bonding method, where the bonding method may include a hybrid bonding method. A hybrid bonding structure may refer to a bonding structure which is formed by two materials, which are of the same kind and are fused at an interface therebetween.

In various embodiments, a three-dimensional semiconductor memory device may include the peripheral circuit structure PS and the cell array structure CS on the peripheral circuit structure PS. Because the cell array structure CS is placed on the peripheral circuit structure PS, a cell capacity per unit area in the semiconductor device may be increased. The peripheral circuit structure PS and the cell array structure CS may be separately fabricated and then may be coupled to each other, where the peripheral circuits PTR may be prevented from being damaged by several thermal treatment processes. Accordingly, it may be possible to improve the electrical and reliability characteristics of the three-dimensional semiconductor memory device.

In various embodiments, the peripheral circuit structure PS may include the first substrate 10, the peripheral circuits PTR, the peripheral circuit lines PLP, the peripheral contact plugs PCP, and the lower insulating layer 50 thereon. The peripheral circuits PTR may be integrated on the top surface of the first substrate 10 and may be configured to control a memory cell array.

In various embodiments, the lower insulating layer 50 may be provided on a top surface of the first substrate 10. The lower insulating layer 50 may include the first lower insulating layer 51, the second lower insulating layer 55, and the etch stop layer 53. The first lower insulating layer 51 may cover the peripheral circuits PTR, the peripheral contact plugs PCP, the peripheral circuit lines PLP, and the first substrate 10. The etch stop layer 53 may be located on the first lower insulating layer 51. The second lower insulating layer 55 may be located on the etch stop layer 53 and the first lower insulating layer 51, where the etch stop layer 53 may be between the second lower insulating layer 55 and the first lower insulating layer 51. In an embodiment, the lower insulating layer 50 may be formed of or include at least one of silicon oxide, silicon nitride, silicon oxynitride, or low-k dielectric materials.

In various embodiments, first bonding pads BP1 may be provided in the second lower insulating layer 55. The second lower insulating layer 55 may not cover the top surfaces of the first bonding pads BP1, where for example, a top surface of the second lower insulating layer 55 may be substantially coplanar with the top surfaces of the first bonding pads BP1. The first bonding pads BP1 may be electrically connected to the peripheral circuits PTR through the peripheral circuit lines PLP and the peripheral contact plugs PCP.

In various embodiments, the cell array structure CS may be provided on the peripheral circuit structure PS. The cell array structure CS may include a memory cell array, including memory cells, which are three-dimensionally arranged on the second substrate 100. The cell array structure CS may include the stack ST, the vertical channel structures VS, the data storage patterns DSP, the cell contact plugs CPLG, the bit lines BL, and the conductive lines CL described with reference to FIGS. 5, 6A, and 6B. The cell array structure CS may further include second bonding pads BP2, an input/output contact plug IOPLG, input/output pads PAD, first and second landing pads LP1 and LP2, an upper insulating layer 300, capping insulating layers 310 and 320, and a passivation layer 330.

In various embodiments, a fifth interlayer insulating layer 170 may be provided on the fourth interlayer insulating layer 160 to cover the bit lines BL and the conductive lines CL. Upper conductive lines UCL may be provided in the fifth interlayer insulating layer 170. The upper conductive lines UCL may be electrically connected to the bit lines BL or the conductive lines CL.

In various embodiments, a sixth interlayer insulating layer 180 may be provided on the fifth interlayer insulating layer 170, and the second bonding pads BP2 may be provided in the sixth interlayer insulating layer 180. The second bonding pads BP2 may be electrically connected to the upper conductive lines UCL. The second bonding pads BP2 may be electrically and physically connected to the first bonding pads BP1 in a hybrid bonding manner. The first and second bonding pads BP1 and BP2, which may be bonded to each other, may have a continuous structure, and there may be no observable interface between the first and second bonding pads BP1 and BP2. The first and second bonding pads BP1 and BP2 may be bonded to form a single object.

In various embodiments, in the connection region CNR, an insulating gapfill layer 110 and a pad insulating layer 115 may be provided on the side surface of the second substrate 100 and the side surface of the source structure CST. The pad insulating layer 115 may be placed between the insulating gapfill layer 110 and the planarization insulating layer 120 to cover the first and second landing pads LP1 and LP2. The insulating gapfill layer 110 and the pad insulating layer 115 may be formed of or include one or more insulating materials (e.g., silicon oxide and silicon nitride).

In various embodiments, in the connection region CNR, the first and second landing pads LP1 and LP2 may be provided in the insulating gapfill layer 110, as shown e.g., in FIG. 10. Each of the first and second landing pads LP1 and LP2 may include a via portion, which is in contact with the input/output pad PAD, and a pad portion, which is connected to the via portion. The via portion may extend from the pad portion into the upper insulating layer 300. The first landing pad LP1 may be positioned closer to the cell array region CAR in the first direction D1, compared with the second landing pad LP2. The pad portion of the first landing pad LP1 may be in contact with the second substrate 100 and the source structure CST. The second landing pad LP2 may be spaced apart from the first landing pad LP1 in the first direction D1. The pad portion of the second landing pad LP2 may be connected to the input/output contact plug IOPLG. The pad portion of the first landing pad LP1 and the pad portion of the second landing pad LP2 may be on a pad insulating layer 115.

In various embodiments, the upper insulating layer 300 may be provided on the second substrate 100, where the upper insulating layer 300 may cover at least a portion of the second substrate 100 and the insulating gapfill layer 110. The input/output pads PAD may be provided on the upper insulating layer 300. The capping insulating layers 310 and 320 and the passivation layer 330 may be sequentially provided on the upper insulating layer 300. The capping insulating layers 310 and 320 may cover the input/output pads PAD. The capping insulating layers 310 and 320 and the passivation layer 330 may have a pad opening OP exposing the input/output pad PAD. In an embodiment, the capping insulating layers 310 and 320 may be formed of or include silicon nitride or silicon oxynitride, and the passivation layer 330 may be formed of or include a polyimide-based material (e.g., photo sensitive polyimide (PSPI)). The input/output pads PAD may be electrically connected to the via portions of the first and second landing pads LP1 and LP2.

In various embodiments, in the connection region CNR, the input/output contact plug IOPLG may penetrate the first and second interlayer insulating layers 130 and 140, the planarization insulating layer 120, and the pad insulating layer 115. The input/output contact plug IOPLG may be in electrical contact with the second landing pad LP2. The input/output contact plug IOPLG may be electrically connected to the input/output pads PAD through the second landing pad LP2.

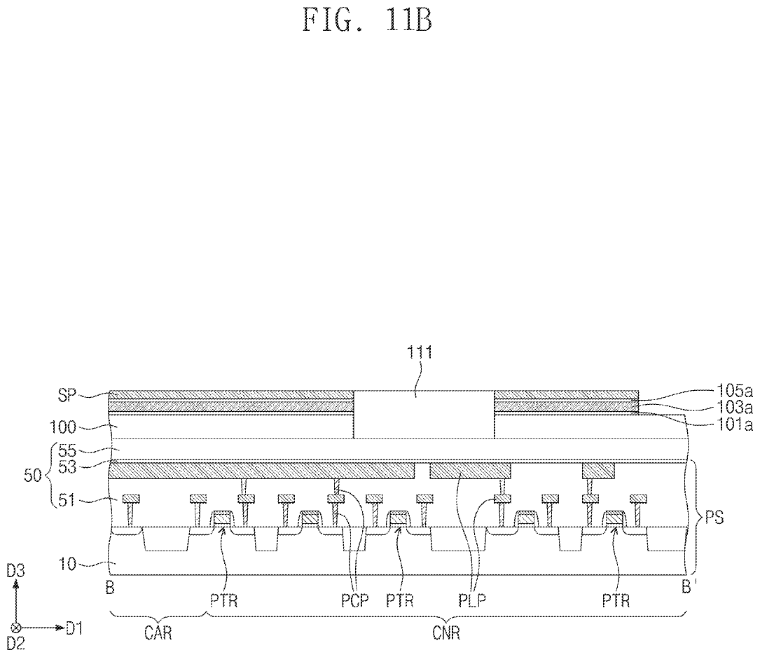

FIGS. 11A to 17B are diagrams illustrating a method of fabricating a three-dimensional semiconductor memory device, according to an embodiment of the inventive concept.

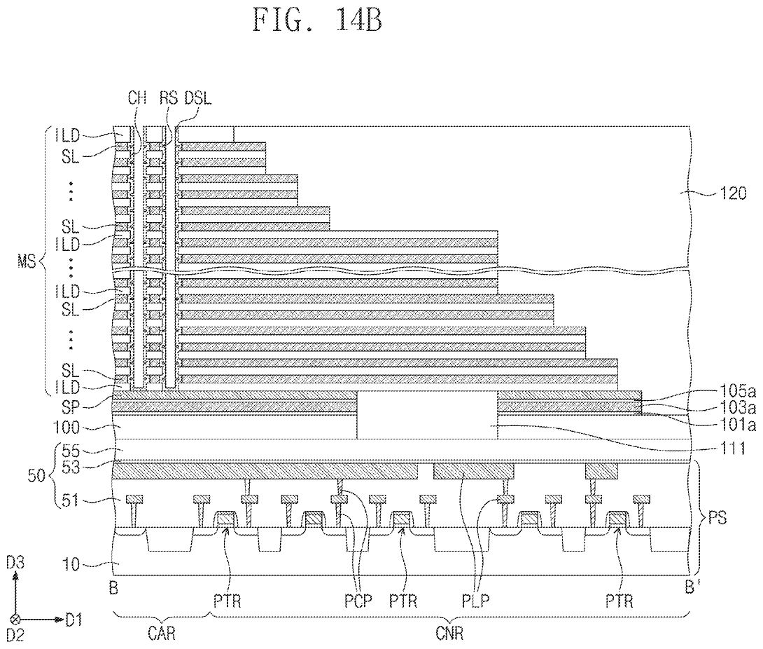

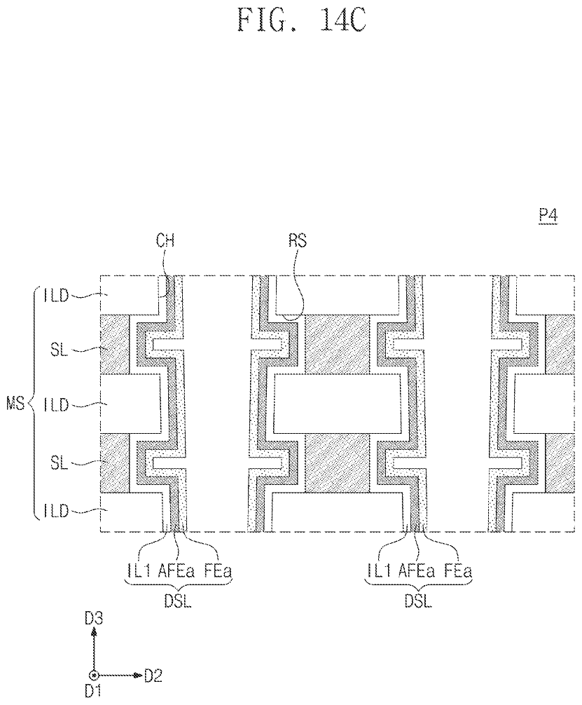

FIGS. 11A, 12A, 13A, 14A, 15A, 16A, and 17A are sectional views taken along a line A-A′ of FIG. 5, FIGS. 11B, 12B, 13B, 14B, 15B, 16B, and 17B are sectional views taken along a line B-B′ of FIG. 5, and FIG. 14C is an enlarged view illustrating a portion P4 of FIG. 14A.

Referring to FIGS. 11A and 11B, the peripheral circuit structure PS may be formed. The formation of the peripheral circuit structure PS may include forming the peripheral circuits PTR on the first substrate 10, forming peripheral interconnection structures PCP and PLP connected to the peripheral circuits PTR, and forming the lower insulating layer 50.

In various embodiments, the peripheral circuits PTR may be formed on an active region, which is defined by a device isolation layer in the first substrate 10. Here, the peripheral circuits PTR may include MOS transistors using the first substrate 10 as channel regions thereof.

In various embodiments, the lower insulating layer 50 may include the first lower insulating layer 51, the second lower insulating layer 55, and the etch stop layer 53. The formation of the lower insulating layer 50 may include sequentially forming the first lower insulating layer 51, the etch stop layer 53, and the second lower insulating layer 55 on the first substrate 10. In an embodiment, the lower insulating layer 50 may include a silicon oxide layer, a silicon nitride layer, a silicon oxynitride layer, and/or a low-k dielectric layer.

In various embodiments, the formation of the peripheral interconnection structures PCP and PLP may include forming the peripheral contact plugs PCP to partially penetrate the first lower insulating layer 51 and forming the peripheral circuit lines PLP connected to the peripheral contact plugs PCP.

In various embodiments, the second substrate 100 may be formed on the lower insulating layer 50, as shown e.g., in FIG. 11B. The second substrate 100 may be formed by depositing a semiconductor material. In an embodiment, the second substrate 100 may be formed of or include at least one of silicon (Si), germanium (Ge), silicon germanium (SiGe), gallium arsenic (GaAs), indium gallium arsenic (InGaAs), or aluminum gallium arsenic (AlGaAs). The second substrate 100 may be formed of or include at least one of doped and/or undoped (e.g., intrinsic) semiconductor materials. The second substrate 100 may have at least one of single crystalline, amorphous, or polycrystalline structures.

In various embodiments, a first dummy insulating layer 101a, a second dummy insulating layer 103a, and a third dummy insulating layer 105a may be sequentially formed on the second substrate 100. The first dummy insulating layer 101a may be formed by thermally oxidizing the top surface of the second substrate 100 or depositing a silicon oxide layer on the top surface of the second substrate 100. The second dummy insulating layer 103a may be formed of or include a material having an etch selectivity with respect to the first dummy insulating layer 101a and the third dummy insulating layer 105a. For example, the second dummy insulating layer 103a may be formed of or include at least one of silicon nitride, silicon oxynitride, silicon carbide, or silicon germanium. The third dummy insulating layer 105a may be formed by depositing a silicon oxide layer on the second dummy insulating layer 103a.

In various embodiments, the first to third dummy insulating layers 101a, 103a, and 105a may have an opening extending therethrough and exposing a portion of the top surface of the second substrate 100. The formation of the opening may include forming a mask pattern and etching the first to third dummy insulating layers 101a, 103a, and 105a using the mask pattern to expose the underlying portion of the second substrate 100.

In various embodiments, the support conductive pattern SP may be deposited to have a uniform thickness on the third dummy insulating layer 105a, where the support conductive pattern SP may have a uniform thickness. The support conductive pattern SP may fill the opening in the first to third dummy insulating layers 101a, 103a, and 105a. The support conductive pattern SP may have a recessed top surface in the opening, where the top surface of the support conductive pattern SP may be below the level of the mold insulating pattern 111. In the opening, the support conductive pattern SP may be in contact with the second substrate 100.

In various embodiments, the mold insulating pattern 111 may be formed to extend through the second substrate 100, the first to third dummy insulating layers 101a, 103a, and 105a, and the support conductive pattern SP. The formation of the mold insulating pattern 111 may include forming a mask pattern on the support conductive pattern SP to expose a portion of the connection region CNR, performing an etching process using the mask pattern to form a hole penetrating the second substrate 100, the first to third dummy insulating layers 101a, 103a, and 105a, and the support conductive pattern SP, filling the hole with an insulating material, and performing a planarization process on the insulating material to expose the top surface of the support conductive pattern SP. The top surface of the support conductive pattern SP may be coplanar with or below the level of the mold insulating pattern 111.

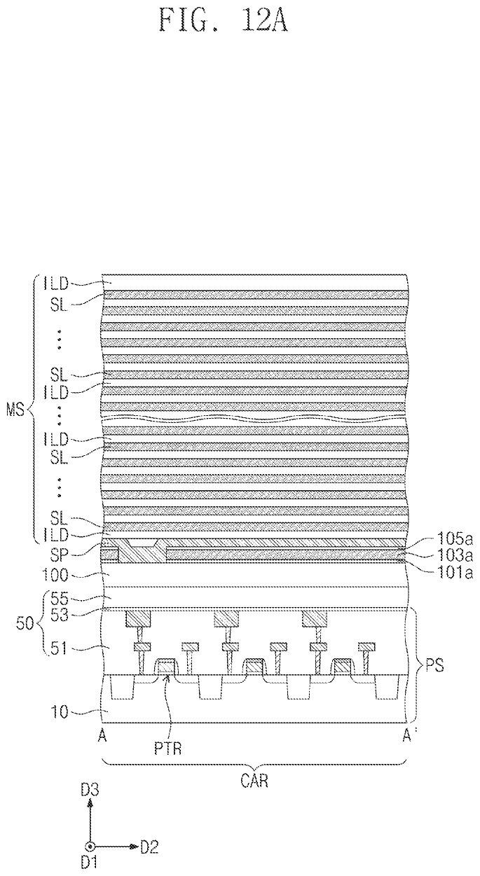

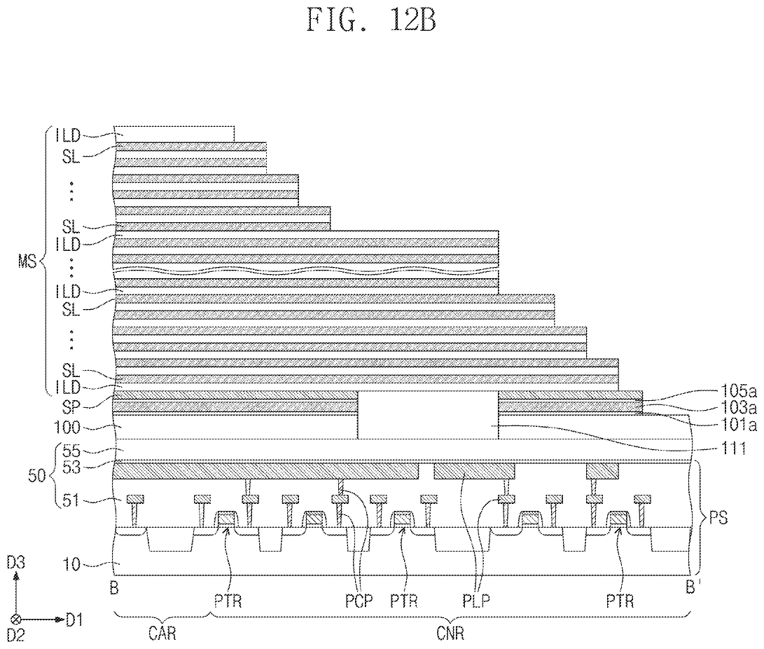

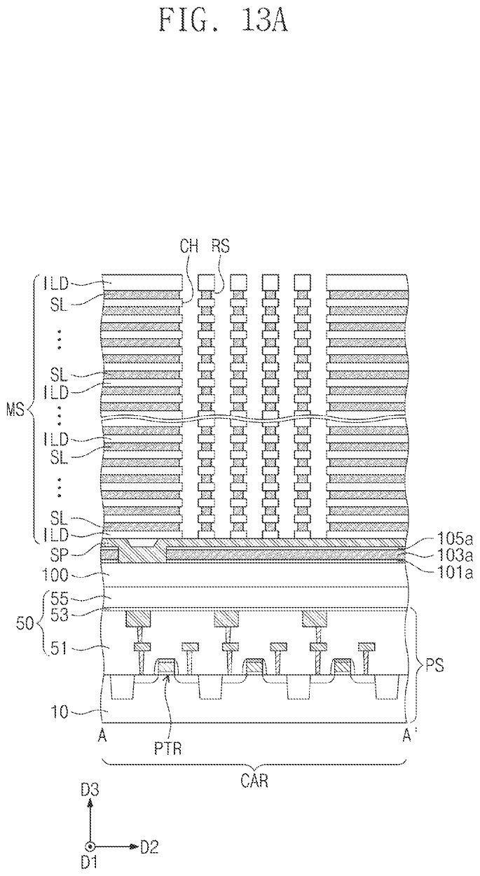

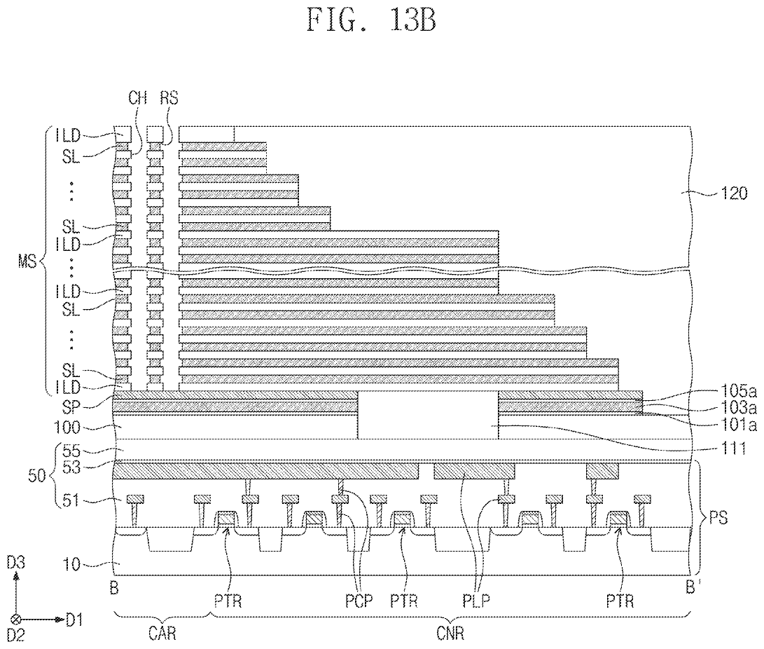

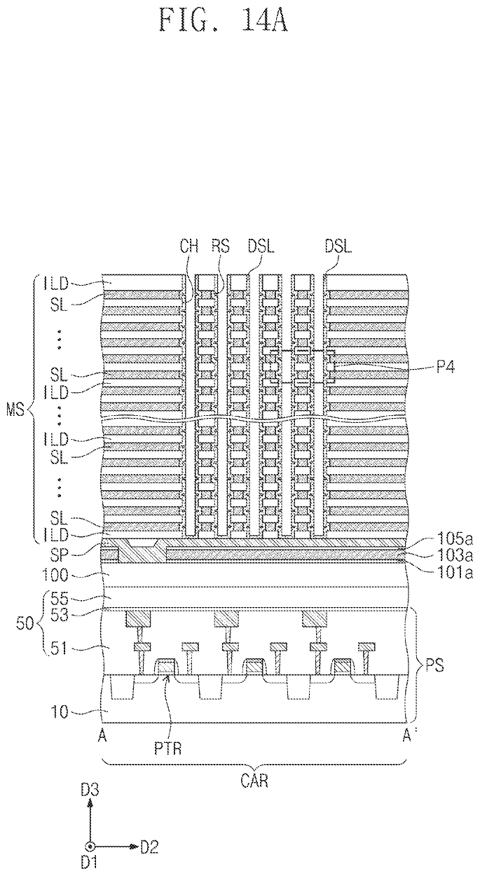

Referring to FIGS. 12A and 12B, a mold structure MS may be formed on the support conductive pattern SP. The formation of the mold structure MS may include forming a layered structure, in which insulating layers ILD and sacrificial layers SL are alternately stacked, and repeatedly performing a patterning process on the layered structure. As a result, the mold structure MS may be formed to have a stepwise structure in the connection region CNR.

In various embodiments, the sacrificial layers SL may be formed of or include a material having an etch selectivity with respect to the insulating layers ILD. The sacrificial layers SL may include an insulating material different from the insulating layers ILD. The sacrificial layers SL may be formed of or include the same insulating material as the second dummy insulating layer 103a, where for example, the sacrificial layers SL may include silicon nitride, and the insulating layers ILD may include silicon oxide.

Referring to FIGS. 13A and 13B, the planarization insulating layer 120 may be formed in the connection region CNR. The planarization insulating layer 120 may cover a staircase structure of the mold structure MS, as shown e.g., in FIG. 13B. The top surface of the planarization insulating layer 120 may be located at the same level as a top surface of the mold structure MS.

In various embodiments, in the cell array region CAR, the channel holes CH may be formed to extend into the mold structure MS, where the channel holes CH may penetrate to the support conductive pattern SP. The formation of the channel holes CH may include forming a mask pattern on the mold structure MS and performing an etching process using the mask pattern to expose a side surface of the mold structure MS and the support conductive pattern SP. For example, the etching process may be an anisotropic dry etching process that is performed using plasma.

After the formation of the channel holes CH, the recess regions RS may be formed. The formation of the recess regions RS may include partially removing the sacrificial layers SL through the channel holes CH. The partial removal of the sacrificial layers SL may be performed by a wet etching process using an etching solution with an etch selectivity. By controlling process parameters (e.g., time and/or temperature) in the wet etching process, it may be possible to adjust a removal amount of the sacrificial layers SL. Because the insulating layers ILD are not removed by the wet etching process, the mold structure MS may have an uneven side surface.

Referring to FIGS. 14A, 14B, and 14C, a data storing layer DSL may be formed to cover the side surfaces of the mold structure MS. The data storing layer DSL may be formed to have a uniform thickness in the channel holes CH and the recess regions RS. The data storing layer DSL may include portions that fill the recess regions RS. The formation of the data storing layer DSL may include sequentially forming a first insulating layer IL1, a preliminary anti-ferroelectric pattern AFEa, and a preliminary ferroelectric pattern FEa, where the first insulating layer IL1, a preliminary anti-ferroelectric pattern AFEa, and a preliminary ferroelectric pattern FEa may be formed on the exposed surfaces of the sacrificial layers SL and the insulating layers ILD.

In various embodiments, the first insulating layer IL1 may be formed to have a uniform thickness on surfaces of the sacrificial layers SL and the insulating layers ILD, which are exposed through the channel holes CH and the recess regions RS. The preliminary anti-ferroelectric pattern AFEa may be formed to have a uniform thickness on the first insulating layer IL1, and the preliminary ferroelectric pattern FEa may be formed to have a uniform thickness on the preliminary anti-ferroelectric pattern AFEa. The first insulating layer IL1, the preliminary anti-ferroelectric pattern AFEa, and the preliminary ferroelectric pattern FEa may have substantially the same profile. The first insulating layer IL1, the preliminary anti-ferroelectric pattern AFEa, and the preliminary ferroelectric pattern FEa may be formed using a deposition process. In an embodiment, the deposition process may include a chemical vapor deposition (CVD) process and/or an atomic layer deposition (ALD) process.

In an embodiment, the formation of the data storing layer DSL may include sequentially forming the first insulating layer IL1, the preliminary ferroelectric pattern FEa, and the preliminary anti-ferroelectric pattern AFEa, where the preliminary ferroelectric pattern FEa may be formed between the first insulating layer IL1 and the preliminary anti-ferroelectric pattern AFEa. The data storage patterns DSP may be formed to include the first insulating pattern IP1, the anti-ferroelectric pattern AFE, and the ferroelectric pattern FE between the first insulating pattern IP1 and the anti-ferroelectric pattern AFE, as shown in FIG. 8B.

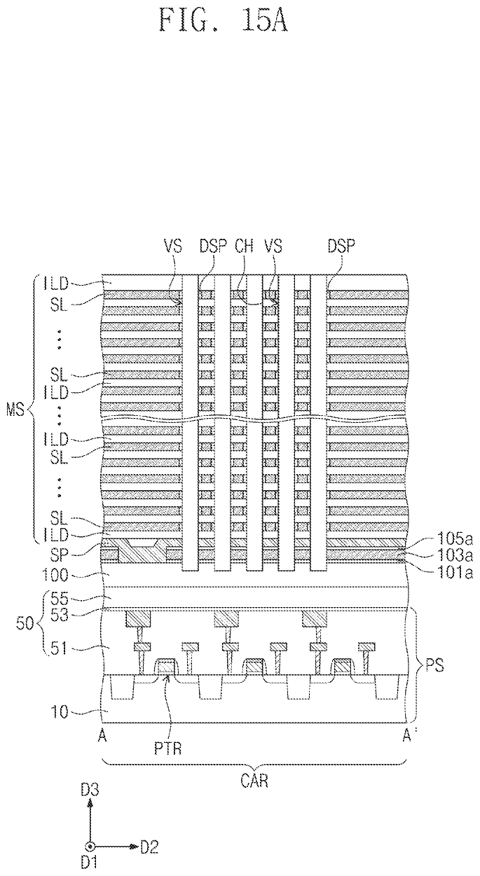

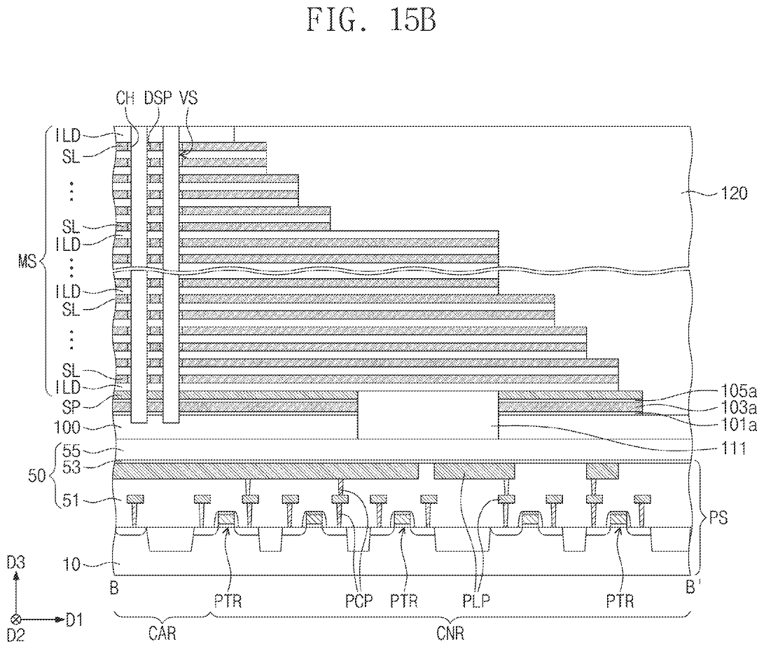

Referring to FIGS. 15A and 15B, an etch-back process may be performed on the mold structure MS. The data storing layer DSL, the support conductive pattern SP, the first to third dummy insulating layers 101a, 103a, and 105a, and the second substrate 100 may be partially removed by the etch-back process. The data storing layer DSL, which is placed outside the recess regions RS of FIG. 14C, may be partially removed to form the data storage patterns DSP, which are placed in the recess regions RS, from the data storing layer DSL. The support conductive pattern SP, the first to third dummy insulating layers 101a, 103a, and 105a, and the second substrate 100 may be exposed through the channel holes CH. A thickness of the uppermost one of the insulating layers ILD may be reduced.

In various embodiments, the vertical channel structures VS may be formed. The formation of the vertical channel structures VS may include sequentially forming the vertical insulating layer VI, the vertical channel pattern VC, and the gapfill insulating pattern GI in the channel holes CH and etching and planarizing the vertical insulating layer VI, the vertical channel pattern VC, and the gapfill insulating pattern GI. The top surfaces of the vertical channel structures VS may be located at the same level as the top surface of the mold structure MS. The vertical channel structures VS may be formed to include the vertical insulating layer VI, the vertical channel pattern VC, and the gapfill insulating pattern GI, as shown in FIGS. 8A and 8B.

In an embodiment, the formation of the vertical channel structures VS may further include forming the ferroelectric layer FEL and the second insulating pattern IP2 and etching and planarizing the ferroelectric layer FEL and the second insulating pattern IP2. In this case, the vertical channel structures VS may be formed to further include the ferroelectric layer FEL and the second insulating pattern IP2, as shown in FIG. 8C.

In an embodiment, forming the gapfill insulating pattern GI, and etching and planarizing the gapfill insulating pattern GI, may be omitted from the process of forming the vertical channel structures VS. In this case, the vertical channel structures VS may be formed to have the vertical channel pattern VC and the vertical insulating layer VI, as shown in FIG. 8D.

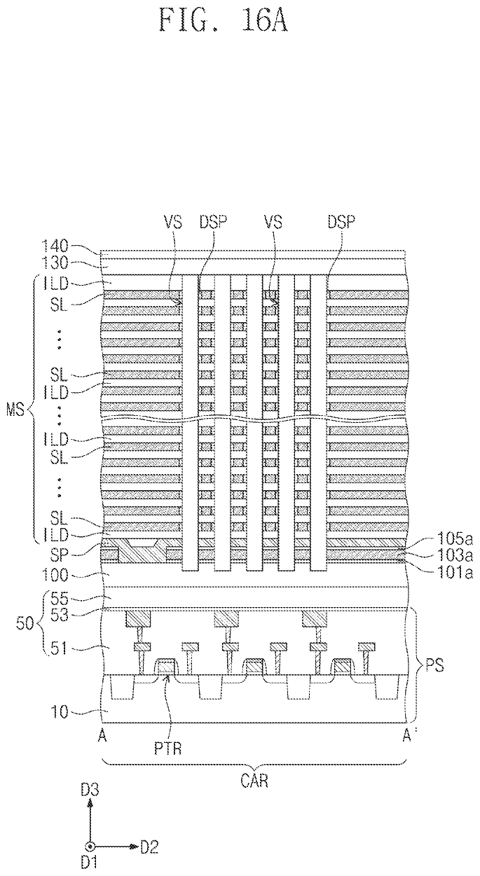

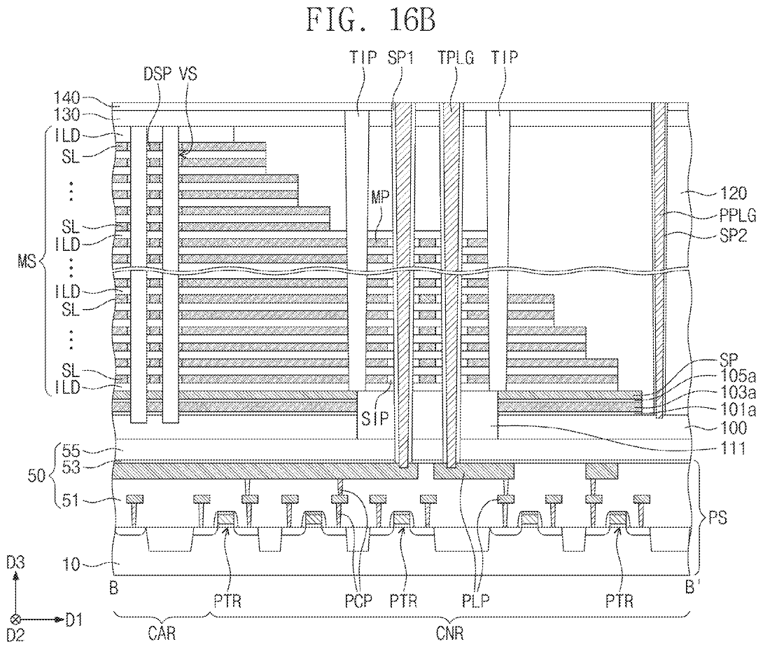

Referring to FIGS. 16A and 16B, the first interlayer insulating layer 130 may be formed on the mold structure MS. The first interlayer insulating layer 130 may cover the top surfaces of the vertical channel structures VS and the top surface of the planarization insulating layer 120.

In various embodiments, the penetration insulating pattern TIP may be formed in the connection region CNR, as shown e.g., in FIG. 16B. The formation of the penetration insulating pattern TIP may include forming a trench to penetrate the first interlayer insulating layer 130, the planarization insulating layer 120, and the mold structure MS, and filling the trench with an insulating material. When viewed in a plan view, the penetration insulating pattern TIP may have a closed-loop shape enclosing the mold insulating pattern 111.

In various embodiments, the second interlayer insulating layer 140 may be formed on the first interlayer insulating layer 130 and a top surface of the penetration insulating pattern TIP. The second interlayer insulating layer 140 may cover the top surface of the first interlayer insulating layer 130 and the top surface of the penetration insulating pattern TIP. The penetration contact plugs TPLG and the peripheral contact plugs PPLG may be formed.

In various embodiments, the formation of the penetration contact plugs TPLG may include forming a penetration hole to extend through the first and second interlayer insulating layers 130 and 140, the planarization insulating layer 120, the mold structure MS, the mold insulating pattern 111, and the second lower insulating layer 55. Portions of the sacrificial layers SL may be removed through the penetration hole to form the sidewall insulating patterns SIP. The first spacer SP1 may be formed to cover an inner side surface of the penetration hole, and the penetration hole may be filled with a conductive material. The penetration contact plugs TPLG may be electrically connected to the peripheral circuit lines PLP of the peripheral circuit structure PS.

In various embodiments, the formation of the peripheral contact plugs PPLG may include forming a penetration hole to penetrate the first and second interlayer insulating layers 130 and 140 and the planarization insulating layer 120, forming the second spacer SP2 to cover an inner side surface of the penetration hole, and filling the penetration hole with a conductive material. The peripheral contact plugs PPLG may be formed to be in contact with the second substrate 100.

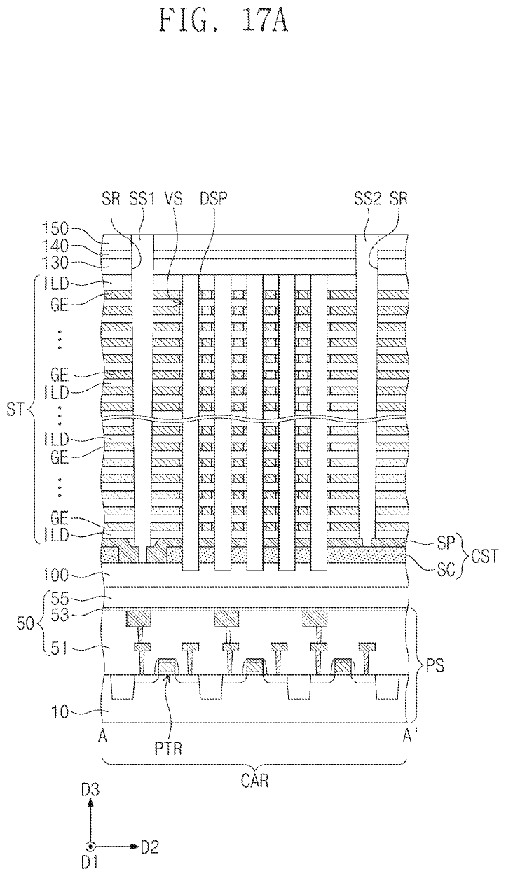

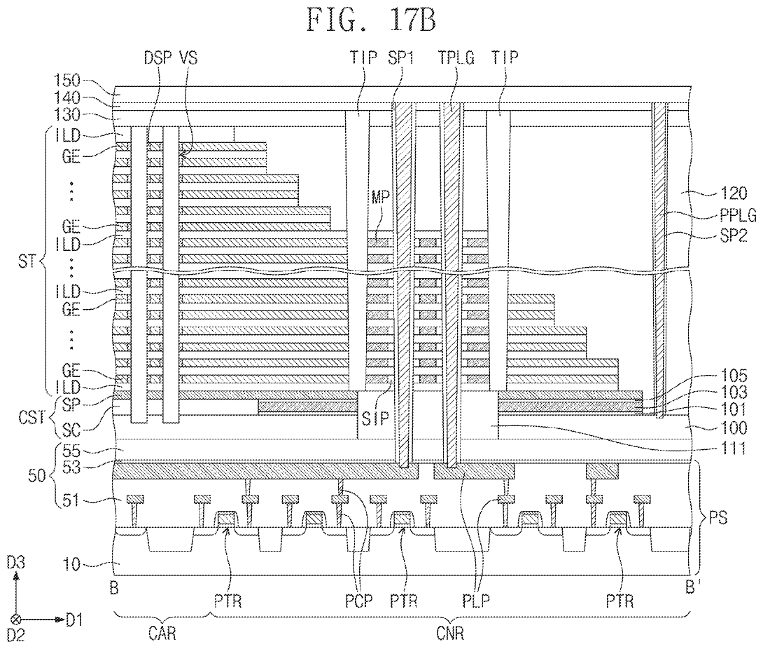

Referring to FIGS. 17A and 17B, the third interlayer insulating layer 150 may be formed on the second interlayer insulating layer 140 to cover the penetration contact plugs TPLG and the peripheral contact plugs PPLG.

In various embodiments, separation trenches SR may be formed to penetrate the mold structure MS. The separation trenches SR may be formed by etching the first to third interlayer insulating layers 130, 140, and 150, the planarization insulating layer 120, and the mold structure MS, where the support conductive pattern SP may serve as an etch stop layer.

In various embodiments, the first to third dummy insulating layers 101a, 103a, and 105a may be partially removed through the separation trenches SR, and the source conductive pattern SC may be formed in an empty space, which is formed by the removal of the first to third dummy insulating layers 101a, 103a, and 105a. The formation of the source conductive pattern SC may include performing an etching process on the first to third dummy insulating layers 101a, 103a, and 105a and the vertical channel structures VS exposed through the separation trenches SR. As described with reference to FIG. 9, the vertical insulating layer VI of the vertical channel structures VS may be partially removed to expose the vertical channel pattern VC. Next, a doped poly silicon layer may be deposited to form the source conductive pattern SC. In this case, the source structure CST may be formed between the second substrate 100 and the mold structure MS.

In various embodiments, the gate electrodes GE may be formed, after the formation of the source structure CST. The formation of the gate electrodes GE may include removing the sacrificial layers SL through an etching process using a material having an etch selectivity with respect to the insulating layers ILD, the vertical channel structures VS, and the source structure CST, and filling an empty space, which is formed by removing the sacrificial layers SL, with a conductive material to form the gate electrodes GE. The sacrificial layers SL in the connection region CNR may not be fully removed, and in this case, the remaining portions of the sacrificial layers SL may form the mold patterns MP. The stack ST may be formed to include the insulating layers ILD and the gate electrodes GE, which are alternately stacked in the third direction D3.

In various embodiments, after the formation of the stack ST, the first and second separation structures SS1 and SS2 may be formed by filling the separation trenches SR with an insulating material.

Referring back to FIGS. 6A and 6B, the fourth interlayer insulating layer 160 may be formed to cover the third interlayer insulating layer 150, the bit line contact plugs BCTa and BCTb may be formed to be connected to the vertical channel structures VS, and the cell contact plugs CPLG and the contact plugs LCT may be formed to be connected to the pad portions GEp of the gate electrodes GE. The bit lines BL and the conductive lines CL may be formed on the fourth interlayer insulating layer 160.

According to an embodiment of the inventive concept, a three-dimensional semiconductor memory device may include data storage patterns, which are vertically spaced apart from each other between a stack and vertical channel structures, and each of the data storage patterns may include a ferroelectric pattern, an anti-ferroelectric pattern, and an insulating pattern. Owing to the anti-ferroelectric pattern in contact with the ferroelectric pattern, programming operation may become easier, and the overall electrostatic capacitance of a nonvolatile memory device may be increased. In addition, the insulating pattern between the ferroelectric pattern and the stack may serve as a charge trap layer of the nonvolatile memory device, and this may make it possible to increase a memory window. Thus, the electrical characteristics of the three-dimensional semiconductor memory device may be improved.

While example embodiments of the inventive concept have been particularly shown and described, it will be understood by one of ordinary skill in the art that variations in form and detail may be made therein without departing from the spirit and scope of the attached claims.

What is claimed is:

1. A three-dimensional semiconductor memory device, comprising:
a stack including alternatingly stacked gate electrodes and insulating layers on a substrate;
vertical channel structures penetrating the stack; and
data storage patterns between the stack and the vertical channel structures,
wherein the data storage patterns are spaced apart from each other in a direction perpendicular to a top surface of the substrate, and
each of the data storage patterns comprises a ferroelectric pattern, an anti-ferroelectric pattern, and a first insulating pattern.

2. The semiconductor memory device of claim 1, wherein the first insulating pattern comprises a vertical portion and horizontal portions extended from the vertical portion, wherein
the vertical portion is in contact with an adjacent one of the gate electrodes, and
the horizontal portions are in contact with adjacent ones of the insulating layers.

3. The semiconductor memory device of claim 2, wherein the anti-ferroelectric pattern is between the first insulating pattern and the ferroelectric pattern.

4. The semiconductor memory device of claim 2, wherein the ferroelectric pattern is between the first insulating pattern and the anti-ferroelectric pattern.

5. The semiconductor memory device of claim 1, wherein the data storage patterns surround the vertical channel structures, when viewed in a plan view.

6. The semiconductor memory device of claim 1, wherein the first insulating pattern and the anti-ferroelectric pattern comprise different materials from each other.

7. The semiconductor memory device of claim 1, wherein the data storage patterns overlap portions of the insulating layers.

8. The semiconductor memory device of claim 1, wherein the data storage patterns are at the same level as the gate electrodes.

9. The semiconductor memory device of claim 1, wherein a thickness of the ferroelectric pattern is greater than a thickness of the anti-ferroelectric pattern and a thickness of the first insulating pattern.

10. The semiconductor memory device of claim 1, wherein each of the vertical channel structures comprises a vertical channel pattern and a vertical insulating layer enclosing a side surface of the vertical channel pattern.

11. The semiconductor memory device of claim 10, wherein each of the vertical channel structures further comprises a ferroelectric layer and a second insulating pattern, and
the ferroelectric layer is between the second insulating pattern and the vertical insulating layer.

12. A three-dimensional semiconductor memory device, comprising:
a substrate including a cell array region and a connection region;
a stack including alternatingly stacked gate electrodes and insulating layers on the substrate;
vertical channel structures on the cell array region that penetrate the stack and electrically connect to the substrate;
a planarization insulating layer on the connection region that cover the stack;
cell contact plugs on the connection region and penetrate the planarization insulating layer, and are electrically connected to the gate electrodes, respectively;
bit lines on the stack and electrically connected to the vertical channel structures; and
data storage patterns between the vertical channel structures and the gate electrodes,
wherein each of the data storage patterns comprises:
a ferroelectric pattern including a ferroelectric material;
an anti-ferroelectric pattern including an anti-ferroelectric material; and
a first insulating pattern including a material different from the anti-ferroelectric pattern.

13. The semiconductor memory device of claim 12, wherein the data storage patterns are spaced apart from each other in a direction perpendicular to a top surface of the substrate and are placed at the same level as the gate electrodes.

14. The semiconductor memory device of claim 12, wherein, in the cell array region, the data storage patterns vertically overlap with portions of the insulating layers.

15. The semiconductor memory device of claim 12, wherein each of the vertical channel structures comprises a vertical channel pattern, a vertical insulating layer, a ferroelectric layer, and a second insulating pattern, and
the second insulating pattern is between the ferroelectric layer and the ferroelectric pattern.

16. The semiconductor memory device of claim 12, wherein a horizontal length of the gate electrodes between the vertical channel structures is less than a horizontal length of the insulating layers between the vertical channel structures.

17. The semiconductor memory device of claim 12, wherein the data storage patterns surround the vertical channel structures, when viewed in a plan view, and
the gate electrodes surround the data storage patterns, when viewed in a plan view.

18. An electronic system, comprising:
a three-dimensional semiconductor memory device including an input/output pad; and
a controller electrically connected to the three-dimensional semiconductor memory device through the input/output pad that is configured to control the three-dimensional semiconductor memory device,
wherein the three-dimensional semiconductor memory device further comprises:
a substrate including a cell array region and a connection region;
a peripheral circuit structure provided on the substrate, the peripheral circuit structure comprising peripheral circuits electrically connected to the input/output pad; and
a cell array structure comprising a stack, wherein the stack includes gate electrodes and insulating layers alternatingly stacked on the peripheral circuit structure, vertical channel structures, that penetrate the stack, and data storage patterns between the gate electrodes and the vertical channel structures,
wherein each of the data storage patterns comprises a ferroelectric pattern, an anti-ferroelectric pattern, and an insulating pattern, and
the ferroelectric pattern and the anti-ferroelectric pattern are between the insulating pattern and the vertical channel structures.

19. The electronic system of claim 18, wherein the data storage patterns are spaced apart from each other in a direction perpendicular to a top surface of the substrate, and
when in a plan view, the stack encloses the data storage patterns, and the data storage patterns enclose the vertical structures.

20. The electronic system of claim 18, wherein the data storage patterns are between the insulating layers.
